(19) United States
(12) Patent Application Publication
(10) Pub. No.: US 2025/0308885 A1
(43) Pub. Date: Oct. 2, 2025

(54) HYDROGEN REDUCTION IN AMORPHOUS CARBON FILMS

(71) Applicant: Lam Research Corporation, Fremont, CA (US)

(72) Inventors: Defu LIANG, Wilsonville, OR (US); Ming LI, West Linn, OR (US); Xin MENG, Ontario, CA (US); Hu KANG, Tualatin, OR (US); Joseph Lindsey WOMACK, Tigard, OR (US); Jing LI, Milpitas, CA (US); Gongcheng YAO, Beaverton, OR (US); Tu HONG, Lake Oswego, OR (US); Chunhai JI, Portland, OR (US); Feng BI, Lake Oswego, OR (US); Niraj RANA, West Linn, OR (US)

(21) Appl. No.: 18/854,520

(22) PCT Filed: Apr. 5, 2023
(86) PCT No.: PCT/US2023/065369

§ 371 Date: Oct. 5, 2024

Related U.S. Application Data
(60) Provisional application No. 63/362,642, filed on Apr. 7, 2022.
(60) Provisional application No. 63/387,787, filed on Dec. 16, 2022.

(51) Int. Cl. H01L 21/02; C23C 16/26; C23C 16/505; C23C 16/52; C23C 16/56; H01J 37/32; H01L 21/324

(52) U.S. Cl. CPC H01L 21/02274; C23C 16/26; C23C 16/505; C23C 16/52; C23C 16/56; H01J 37/32449; H01L 21/02115; H01L 21/324; H01J 37/32082; H01J 37/32522; H01J 37/32816; H01J 2237/327; H01J 2237/3321

(57) ABSTRACT

Provided herein are examples of methods and related apparatus for depositing an ashable hardmask (AHM) on a substrate using a process gas including hydrocarbons and halide-containing species and pulsed low frequency (LF) power. Halide-containing species may decrease the hydrogen content of the AHM, and a plasma using pulsed LF power may improve mechanical properties of the AHM. Also provided herein are examples of annealed hardmasks and examples of processes for annealing hardmasks.

### BACKGROUND

Amorphous carbon films may be used as hardmasks and etch stop layers in semiconductor processing, including in memory and logic device fabrication. These films are also known as ashable hardmasks (AHMs) because they may be removed by an ashing technique. As aspect ratios in lithography increase, AHMs require higher etch selectivity. Current methods of forming highly selective AHMs using plasma enhanced chemical vapor deposition (PECVD) processes result in AHMs with high stress, limiting the AHMs' usefulness as hardmasks. Accordingly, it is desirable to produce AHMs having high etch selectivity, but low stress.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Disclosed herein are methods and systems of forming an ashable hardmask (AHM) film, a method including: receiving a substrate in a processing chamber; exposing the substrate in the processing chamber to a process gas including one or more hydrocarbon precursors and one or more halide-containing species; and depositing on the substrate the AHM film by a plasma enhanced chemical vapor deposition (PECVD) process using the process gas, wherein the PECVD process includes: igniting a plasma generated by a dual radio frequency (RF) plasma source including a high frequency (HF) component and a low frequency (LF) component; wherein the HF component power is constant during deposition, and wherein the LF component power is pulsed, with at least 1250 W per 300 mm wafer and a duty cycle between 10% and 75%.

In some examples, the one or more halide-containing species are a fluorine-containing species. In some examples, the one or more halide-containing species include SF₆, CF₄, or both. In some examples, the one or more hydrocarbon precursors include acetylene, propylene, methane, or any combinations thereof. In some examples, a flow rate of the one or more halide-containing species is between 1% and 20% of a flow rate of the one or more hydrocarbon precursors. In some examples, a flow rate of the one or more halide-containing species is between 5% and 15% of a flow rate of the one or more hydrocarbon precursors. In some examples, a flow rate of the one or more hydrocarbon precursors is between 100 sccm and 200 sccm. In some examples, the HF component power is at least 350 W per 300 mm wafer. In some examples, the processing chamber is at a temperature between 150° C. and 550° C. during the PECVD process. In some examples, the processing chamber is at a pressure between 0.5 torr and 5 torr during the PECVD process. In some examples, exposing the substrate to the one or more halide-containing species occurs after igniting the plasma, and wherein the one or more halide-containing species is flowed into the plasma. In some examples, the AHM film is deposited on a layer of the substrate including poly-Si, SiO₂, Si₃N₄, or any combinations thereof. In some examples, the AHM film has a modulus of at least 120 GPa. In some examples, the AHM film has a hardness of at least 14 GPa. In some examples, the AHM film has a hardness between 14 GPa and 16 GPa. In some examples, the AHM film has a hydrogen content less than 20% atomic. In some examples, the AHM film has a hydrogen content less than 15% atomic.

Examples also are disclosed that relate to annealed carbon hardmasks. One example provides a method of processing a substrate. The substrate comprises a carbon hardmask. The method comprises placing the substrate in an annealing tool. The carbon hardmask has a first stress and a first hydrogen content. The method further comprises annealing the substrate to form an annealed carbon hardmask that has a second stress and a second hydrogen content. The second stress is lower than the first stress. The second hydrogen content is lower than the first hydrogen content. In some such examples, the substrate comprises a three-dimensional integrated circuit mold stack on which the carbon hardmask is disposed. In some such examples, the second, lower hydrogen content of the annealed carbon hardmask alternatively or additionally is less than or equal to 10 atomic percent. In some such examples, the second, lower stress of the annealed carbon hardmask alternatively or additionally is greater than or equal to 1 MPa (megapascal) and less than or equal to 100 MPa. In some such examples, annealing the substrate such that the annealed carbon hardmask comprises the second, lower stress alternatively or additionally comprises annealing the substrate such that the annealed carbon hardmask exhibits a modulus of elasticity greater than or equal to 60 GPa (gigapascal) and less than or equal to 250 GPa. In some such examples, annealing the substrate such that the annealed carbon hardmask comprises the second, lower stress alternatively or additionally comprises annealing the substrate such that the annealed carbon hardmask exhibits a change of less than or equal to 15% in average grain size compared to the carbon hardmask. In some such examples, annealing the substrate such that the annealed carbon hardmask comprises the second, lower stress alternatively or additionally comprises annealing the substrate such that the annealed carbon hardmask exhibits a change of less than or equal to 10% in sp³ carbon content compared to the carbon hardmask. In some such examples, annealing the substrate such that the annealed carbon hardmask comprises the second, lower stress alternatively or additionally comprises annealing the substrate at a temperature within a temperature range of 500-1000° C.

Another example provides a method of processing a substrate. The method comprises depositing a carbon hardmask, annealing the carbon hardmask to form an annealed carbon hardmask, patterning the annealed carbon hardmask, and etching the substrate. In some such examples, depositing the carbon hardmask alternatively or additionally comprises depositing the carbon hardmask such that the carbon hardmask exhibits a modulus of elasticity greater than or equal to 60 GPa and less than or equal to 250 GPa. In some such examples, depositing the carbon hardmask alternatively or additionally comprises depositing the carbon hardmask using one of thermal chemical vapor deposition (CVD), plasma enhanced chemical vapor deposition (PECVD) or remote plasma enhanced chemical vapor deposition (RPECVD). In some such examples, annealing the carbon hardmask alternatively or additionally comprises annealing the carbon hardmask under an inert atmosphere. In some such examples, annealing the carbon hardmask alternatively or additionally comprises annealing the carbon hardmask at a temperature that is greater than a deposition temperature and within a temperature range of 500-1000° C. In some such examples, annealing the carbon hardmask alternatively or additionally comprises annealing the carbon hardmask such that the annealed carbon hardmask exhibits a hydrogen content of less than or equal to 10 atomic percent. In some such examples, annealing the carbon hardmask alternatively or additionally comprises annealing the carbon hardmask such that the annealed carbon hardmask exhibits a stress that is greater than or equal to 1 MPa and less than or equal to 100 MPa. In some such examples, annealing the carbon hardmask alternatively or additionally comprises annealing the carbon hardmask such that the annealed carbon hardmask exhibits a modulus of elasticity greater than or equal to 60 GPa and less than or equal to 250 GPa. In some such examples, annealing the carbon hardmask alternatively or additionally comprises annealing the carbon hardmask such that the annealed carbon hardmask exhibits a change of less than or equal to 15% in an average grain size compared to the carbon hardmask. In some such examples, annealing the carbon hardmask alternatively or additionally comprises annealing the carbon hardmask such that the annealed carbon hardmask exhibits a change of less than or equal to 10% in sp³ carbon content compared to the carbon hardmask.

Another example provides a structure in a 3D memory fabrication process. The structure comprises a substrate and an annealed carbon hardmask disposed on a substrate. The annealed carbon hardmask film has a modulus of elasticity of greater than or equal to 60 GPa and less than or equal to 250 GPa and a stress that is greater than or equal to 1 MPa and less than or equal to 100 MPa. In some such examples, the annealed carbon hardmask alternatively or additionally has a hydrogen content of less than or equal to 10 atomic percent.

These and other features of the disclosed examples will be described in detail below with reference to the associated drawings.

### BRIEF DESCRIPTION OF DRAWINGS

FIG. 1 is a process flow diagram showing relevant operations of methods of using ashable hardmasks (AHM) in etching operations according to various examples.

FIG. 2 presents schematic illustrations of etching stacks of alternating layers in one example.

FIG. 3 is a process flow diagram showing relevant operations of methods of forming ashable hardmasks according to various examples herein.

FIG. 4 is a table of film properties for AHM deposited using various process gases.

FIG. 5 presents FTIR spectra of an ashable hardmask for different proportions of SF₆.

FIG. 6 presents FTIR spectra of an ashable hardmask for different proportions of CF₄.

FIG. 7 shows a schematic illustration of a plasma enhanced chemical vapor deposition (PECVD) chamber suitable for practicing various examples.

FIGS. 8A-8E schematically show an example etching process utilizing a carbon hardmask with insufficient etch selectivity for an etching process.

FIGS. 9A-9F schematically show an example etching process using an annealed carbon hardmask with sufficient etch selectivity for the etching process of FIGS. 1A-1E.

FIG. 10 shows a flow diagram illustrating an example process to form an annealed carbon hardmask.

FIG. 11 shows a flow diagram illustrating an example process to deposit a carbon hardmask, to anneal the carbon hardmask, and to use the annealed carbon hardmask in an etching process.

FIG. 12 shows a block diagram of an example deposition tool.

FIG. 13 shows a block diagram of an example annealing tool.

FIG. 14 shows another schematic illustration of another plasma enhanced chemical vapor deposition (PECVD) chamber suitable for practicing various examples.

FIG. 15 shows a schematic illustration of a module cluster suitable for practicing various examples.

### DETAILED DESCRIPTION

The term “alkane” generally represents compounds comprising a general formula CₙH₂ₙ₊₂. Example alkanes include methane, ethane, propane, and butane. Example alkanes that may be suitable for use as a carbon-containing precursor as disclosed herein include alkanes in which n=1 to 10.

The term “alkene” generally represents hydrocarbon compounds comprising at least one carbon-carbon double bond. Alkenes comprising one carbon-carbon double bond have a general formula of CₙH₂ₙ. Example alkenes include ethylene, propylene, and butylenes. Alkenes may have more than one carbon-carbon double bond, such as dienes, allenes, and cumulenes. Example alkenes that may be suitable for use as a carbon-containing precursor include alkenes in which n=2 to 10.

The term “alkyl amine” generally represents hydrocarbon compounds comprising a nitrogen with 1 to 3 alkyl substituents and 0 to 2 H substituents. Alkyl amines may comprise primary, secondary, tertiary, and cyclic amines. Examples of alkyl amines suitable for use as a carbon-containing precursor include methylamine, dimethylamine, trimethylamine, and piperidine.

The term “alkyne” generally represents hydrocarbon compounds comprising at least one carbon-carbon triple bond. Alkynes comprising one carbon-carbon triple bond have a general formula of CₙH₂ₙ₋₂. Alkynes may have more than one carbon-carbon triple bond, such as diynes, which have two carbon-carbon triple bonds. Example alkynes suitable for use as a carbon-containing precursor may include alkynes in which n=2 to 10.

The terms “anneal”, “annealing”, and variants thereof generally represent a process of heating a carbon hardmask for a period of time after deposition. Annealing can be used for such purposes as stress liberation, removal of volatile species, structural improvement, grain size and/or surface roughness control.

The term “annealing tool” generally represents a tool that is used for annealing substrates. An annealing tool is configured to expose a substrate to elevated temperatures (for example, greater than or equal to 400° C.) under a controlled gaseous environment. An annealing tool also can be referred to as a furnace.

The term “carbon-containing precursor” generally represents a carbon-containing compound that can be introduced into a processing chamber in gas phase to form a carbon hardmask on a substrate in the processing chamber. A carbon-containing precursor can comprise a carbon-containing gas, such as a low molecular-weight hydrocarbon. Example carbon-containing precursors include alkanes having a general formula CₙH₂ₙ₊₂ where n is an integer in a range of 1 to 10 (such as methane, ethane, etc.), alkenes having a general formula CₙH₂ₙ where n=2 to 10 (such as ethylene, propylene, etc.), and alkynes having a general formula CₙH₂ₙ₋₂ where n=2 to 10 (such as acetylene, propyne, etc.), that are gas-phase under processing conditions. Other examples of carbon-containing precursors can comprise aliphatic and aromatic cyclic hydrocarbons, nitrogen-containing compounds including alkyl amines, and oxygen-containing compounds including alcohols, ketones, esters, aldehydes, and ethers, that are gas-phase under processing conditions.

The terms “carbon hardmask” and “ashable hardmask” (AHM) generally represent a layer of carbon used as a selective film in an etching process. A carbon hardmask may comprise amorphous carbon in some examples. Amorphous carbon may comprise both sp² and sp³ carbon.

The term “chemical vapor deposition” generally represents a process in which a film is formed on a substrate by a continuous flow of reactive gas phase precursors. Plasma-enhanced CVD (PECVD) utilizes a plasma to form reactive species from the gas phase precursors to facilitate film formation. Thermal CVD (TCVD) utilizes heat to facilitate film formation. Remote plasma enhanced CVD (RPECVD) utilizes a remote plasma to form reactive species from the gas phase precursors to facilitate film formation.

The term “dual radiofrequency plasma source” generally represents a set of components configured to form a plasma using radiofrequency energy of two different frequencies. A dual radiofrequency plasma source can form a plasma with a high frequency component and a low frequency component. The terms “high frequency component” and “low frequency component” are with reference to one another and can have any suitable values.

The term “duty cycle” generally represents a percentage of time that power to an electronic component is on. Duty cycle can be defined by the equation DC=tₒₙ/(tₒₙ+t_{off}), where tₒₙ is a time duration that the power is on and t_{off} is a duration of time that the power is off.

The terms “etch”, “etching”, and variants thereof generally represent a process of removing material from a substrate surface. An etching process can use chemical and/or physical material removal mechanisms. A dry etching process is an etching process that utilizes gas phase etchants. A wet etching process is an etching process that utilizes liquid-phase etchants.

The terms “etch selectivity”, “selectivity”, and variants thereof generally represent a ratio of the etch rate of one material to the etch rate of another material.

The term “flow control hardware” generally represents components configured to place one or more chemical sources in fluid connection with a processing chamber. Flow control hardware may comprise one or more mass flow controllers and/or valves, for example. Example chemical sources include film precursor sources, inert gas sources, and reactant gas sources.

The term “grain” generally represents a short-range arrangement of atoms in a film or a layer. Grains may differ in size, shape, orientation, and crystallinity.

The term “grain size” generally represents a diameter of an individual grain of a film material. A grain size of a film material may be determined using various measurement techniques. An example measurement technique for measuring grain size is Raman spectroscopy.

The term “halide-containing species” generally represents a molecule with a halogen anion. Example halide-containing species include fluorine-containing species, chlorine-containing species, and bromine-containing species.

The term “hardness” generally represents a resistance of a material to localized plastic deformation.

The term “high aspect ratio” generally represents features with the ratio of the height of the feature to the width of the feature in the range of 1:1 to 100:1 (height:width).

The term “mold stack” generally represents a structure comprising a plurality of alternating material layers that is formed in a process of manufacturing a three dimensional (3D) integrated circuit. In some examples, a mold stack can comprise alternating oxide and nitride layers. In other examples, a mold stack can comprise alternating oxide and polycrystalline silicon (polysilicon) layers. In further examples, a mold stack can comprise any other suitable alternating material layers.

The terms “modulus” and “modulus of elasticity” generally represent a unit of measurement of a resistance of a material to being deformed elastically when subject to an applied stress. The modulus of elasticity is a measure of the mechanical strength of a material.

The term “patterning” generally represents a process of forming a structure on a substrate that selectively masks or exposes selected substrate regions for topology generation in a subsequent deposition or etching process.

The term “plasma” generally represents a gas comprising cations and free electrons.

The term “process gas” generally represents a gas or mixture of gases introduced into a processing chamber when performing a process on a substrate.

The term “processing chamber” generally represents an enclosure in which chemical and/or physical processes are performed on substrates. The pressure, temperature and atmospheric composition within a processing chamber can be controllable to perform the chemical and/or physical processes.

The term “processing tool” generally represents a machine comprising a processing chamber and other hardware configured to enable processing to be carried out in the processing chamber.

The terms “purge” generally represents a process in which unwanted species are removed from a processing chamber.

The term “reactive ion etching (RIE)” generally represents a dry etching process involving accelerating a chemically reactive species (ions) toward a substrate in a low-pressure environment.

The term “remote plasma” generally represents a plasma used to produce reactive chemical species at a location remote from a substrate being processed.

The term “sp² carbon” generally represents a carbon atom bound to three other atoms in a generally trigonal planar arrangement.

The term “sp³ carbon” generally represents a carbon atom bound to four other atoms in a generally tetragonal arrangement.

The term “stress” generally refers to a force per unit area that produces strain in a film or a layer. Stress can be calculated by measuring a change in radius of curvature of a substrate caused by the deposition of a layer on the substrate. When the change in the radius of curvature is positive, the stress can be referred to as “tensile stress”. When the change in the radius of curvature is negative, the stress can be referred to as “compressive stress”.

The term “substrate” generally represents any object on which a film can be deposited.

The term “three dimensional integrated circuit” generally represents a structure where integrated circuit elements are layered vertically in addition to being arranged horizontally across a wafer. Example 3D integrated circuits comprise 3D memory devices. Example 3D memory devices comprise 3D NAND flash, 3D NOR and 3D DRAM.

The term “3D DRAM” is an acronym for three-dimensional dynamic random-access memory.

The term “3D NAND” is an acronym for three-dimensional NOT AND memory, and generally represents memory architectures based upon NOT AND logic gates.

The term “3D NOR” is an acronym for three-dimensional NOT OR memory, and generally represents memory architectures based upon NOT OR logic gates.

The term “atomic percent” generally represents a number of atoms of an element compared to a total number of atoms in a composition.

Semiconductor device processing involves formation of multi-layer stacks which may be used for fabrication of various three-dimensional devices such as 3D NAND structures. Some stacks include multiple alternating layers of dielectric and conducting material, each layer of which may be about 10 nm or thicker. One approach to forming such stacks involves deposition of multiple alternating layers of oxide and nitride material (ONON multiple layer deposition), followed by selective removal of material and backfill deposition of metal into spaces where the nitride material previously occupied. Another approach is to directly pattern a stack of multiple, alternating layers of oxide and polysilicon (or “poly” as used elsewhere herein) where polysilicon remains as the conducting layer. These methods may be used to fabricate 3D NAND structures.

Etching of the stack may be performed using a patterned amorphous carbon film. An amorphous carbon film may also be referred to as an ashable hardmask (AHM). The amorphous carbon layer may be suitable as a hardmask that has a high selectivity during an etch process of the stack. High selectivity is determined in the context of a particular etch chemistry. For a particular etch chemistry, the underlying substrate, e.g., the ONON layers, etches much faster than a hardmask, e.g., an amorphous carbon layer. For various applications described herein the underlying substrate contains silicon oxide, silicon nitride, and/or polysilicon.

For 3D NAND applications, ashable hardmasks may be carbon based and more than about 1.5 micrometers thick. Such thicknesses may be necessary for applications that require etching high aspect ratio features such as those used to form some memory devices such as 3D NAND devices. Sometimes, or in certain examples, applications using amorphous carbon hardmasks produced as described herein etch a stack of alternating layers of silicon oxide and silicon nitride or a stack of alternating layers of polysilicon and silicon oxide. A large contributor to the costs in 3D NAND is the time to deposit AHMs, which, at a rate of about 0.25 micrometers/min and a 2 μm thick target layer, may take 8+ minutes to deposit. Thus, it is desirable to increase the etch selectivity of the AHM to allow for etching of underlying layers with a thinner AHM.

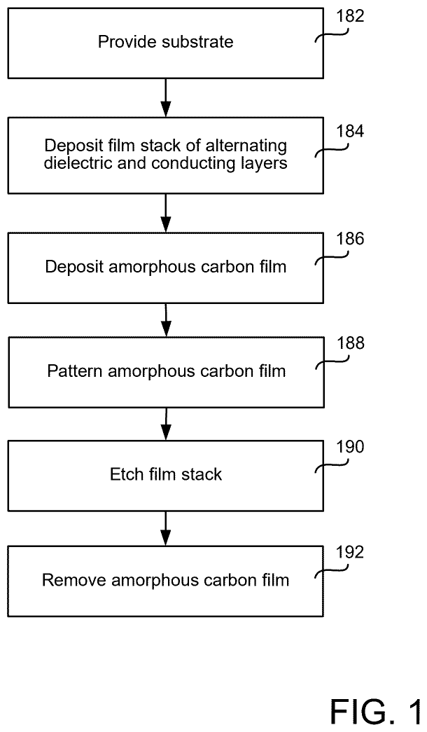

FIG. 1 shows a process flow diagram of operations performed in accordance with a method for forming a 3D NAND structure. In operation 182, a substrate is provided. In various examples, the substrate is a semiconductor substrate. The substrate may be a silicon wafer, e.g., a 200-mm wafer, a 300-mm wafer, or a 450-mm wafer, including wafers having one or more layers of material, such as dielectric, conducting, or semi-conducting material deposited thereon. In operation 184, a film stack of alternating dielectric and conducting layers is deposited on the substrate. In some examples, the dielectric layer is an oxide layer. In various examples, the oxide layer deposited is a silicon oxide layer. In various examples, the conducting layer is a nitride layer, e.g., a silicon nitride layer. In some examples, the conducting layer is a polysilicon layer. Each dielectric and conducting layer is deposited to about the same thickness, such as between about 10 nm and about 100 nm, or about 350 Å in some examples. The oxide layers may be deposited at a deposition temperature of between about room temperature and about 600° C. It will be understood that “deposition temperature” (or “substrate temperature”) as used herein refers to the temperature that the pedestal holding the substrate is set to during deposition.

Oxide and conducting layers for forming the alternating oxide and nitride film stack may be deposited using any suitable technique, such as atomic layer deposition (ALD), plasma enhanced atomic layer deposition (PEALD), chemical vapor deposition (CVD), plasma enhanced chemical vapor deposition (PECVD), physical vapor deposition (PVD), or sputtering. In various examples, the oxide and nitride layers are deposited by PECVD.

The film stack may include between 48 and 512 layers of alternating dielectric and conducting layers, whereby each dielectric or conducting layer constitutes one layer. In some examples, the film stack may include less than 48 layers, or greater than 512 layers of alternating dielectric and conducting layers, depending on the application. The film stack including the alternating oxide and nitride layers may be referred to as an ONON stack. While the film stack described may involve alternating oxide and nitride layers, it will be understood that additional layers may also be included in the stack, and further that other materials may be used for alternating layers that are not oxide and not nitride layers. For example, in some cases, a silicon germanium layer may be used in lieu of a nitride or silicon nitride layer. Other additional layers that may be on the stack include silicon-containing layers, germanium-containing layers, or both. Example silicon-containing layers include doped and undoped silicon carbide layers, doped and undoped polysilicon layers, amorphous silicon layers, doped and undoped silicon oxide layers, and doped and undoped silicon nitride layers. Dopants may include non-metal dopants. For example, doped silicon carbide layer is an oxygen-doped silicon carbide. In another example, doped silicon carbide layer is a nitrogen-doped silicon carbide. Further discussion of depositing and etching layers for 3D NAND applications may be found in Application PCT US2019/050369, filed Sep. 10, 2019.

In operation 186, an amorphous carbon film is formed on the substrate. The amorphous carbon film has various properties described herein that make it suitable as a mask for etching the underlying substrate. For certain applications, the film is at least about 1 μm thick. In certain examples, the film is at least about 1.5 μm thick. In certain examples, the film is at least about 2 μm thick. In some examples, the film is between about 1 μm and about 2 μm thick. In operation 188, the amorphous carbon film is patterned such that portions of the underlying substrate are exposed. Patterning may be accomplished by, e.g., a lithography process.

In operation 190, the film stack is etched. The etch chemistry used is selective to the amorphous carbon film compared to the underlying substrate, such that the amorphous carbon film is etched at a lower rate than the layers of the film stack. Examples of etches can include radical and/or ionic-based etches. Examples of etch chemistries can include halogen-based etch chemistries such as fluorine-containing, bromine-containing, and chlorine-containing etch chemistries. For example, capacitively-coupled plasmas generated from fluorocarbon-containing process gases may be used to selectively etch oxide layers. Specific examples of process gases include CₓF_{y}-containing process gases, optionally with oxygen (O₂) and an inert gas, such as C₄H₈/CH₂F₂/O₂/Ar. In certain examples, an amorphous carbon layer is used as a hardmask in an etch process in which etch species are generated in a plasma.

Finally, in operation 192 the amorphous carbon film is removed, for example by a technique referred to as ashing, plasma ashing, or dry stripping. Ashing may be performed by an oxygen-rich dry etch. Often, oxygen, in the form of, e.g., O₂, N₂O, and NO, is introduced in a chamber under vacuum and RF power creates oxygen radicals in plasma to react with the AHM and oxidize it to water (H₂O), carbon monoxide (CO), and carbon dioxide (CO₂). Optionally, any remaining AHM residue may also be removed by wet or dry etching processes after ashing. The result is a patterned substrate layer.

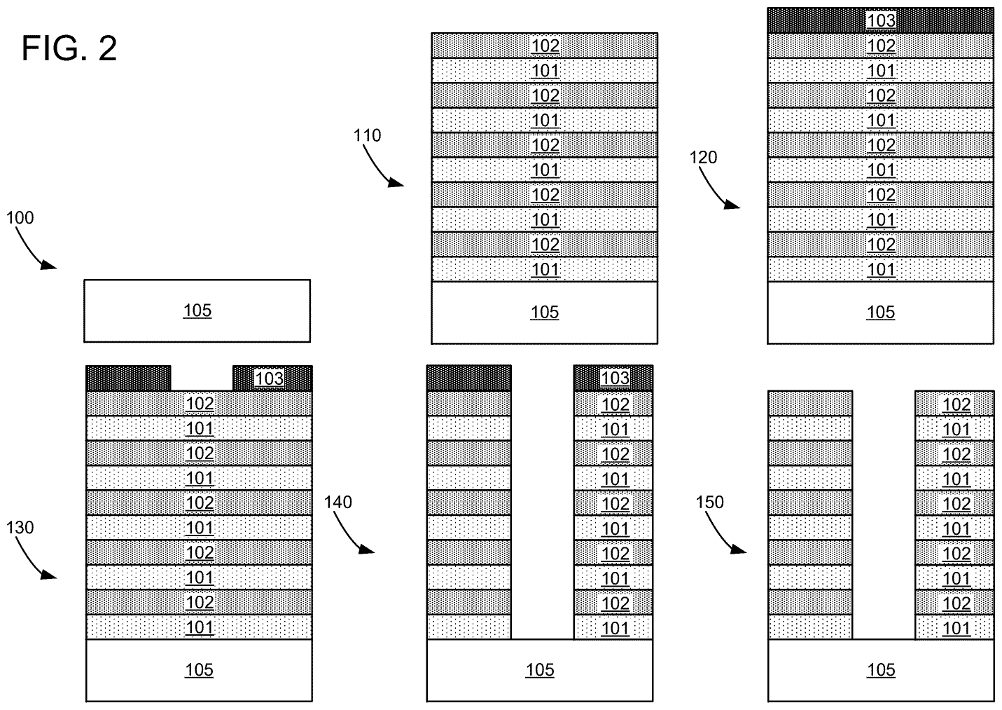

FIG. 2 provides schematic illustrations 100-150 of operations 182-192 of FIG. 1. In diagram 100, a substrate 105 is provided. Substrate 105 may be a silicon wafer having one or more layers previously formed thereon. In diagram 110, alternating layers of oxide (101) and nitride (102) films are deposited on the substrate 105. Note that while the structure shown in FIG. 2 shows an oxide deposited first, followed by nitride, oxide, nitride, etc., nitride may be deposited first, followed by oxide, nitride, oxide, etc.

In diagram 120, an amorphous carbon film 103 is deposited on top of the stack of oxide and nitride films. Details of this process are discussed further herein. In diagram 130, the amorphous carbon film 103 is patterned to expose portions of the underlying stack. The exposed portions of the amorphous carbon film 103 define regions where high aspect ratio features will be etched. In diagram 140, the underlying stack is etched, using the amorphous carbon film 103 as a mask, to form various features in the stack of alternating layers. In diagram 150, the amorphous carbon film 103 is removed, resulting in an etched stack of alternating layers of oxide and nitride films having various features.

In some examples, features to be etched using an AHM as described herein may have an aspect ratio of about 10:1 to about 1000:1. In some examples, an opening size of the features may include about 20-100 nm across.

Certain processes for depositing amorphous carbon hardmasks employ a carbon precursor, which may be a hydrocarbon such as propylene. In some cases, a hydrocarbon precursor has a relatively high carbon to hydrogen ratio, such as acetylene. In some examples, propylene is an advantageous carbon precursor due to a lower tendency to polymerize and clog holes in showerheads and deposit on sensitive components of a deposition chamber. Propylene may also be advantageous for safety concerns at the higher pressures and temperatures employed for processes as described herein. Other hydrocarbon species may also be used, including methane, propylene, acetylene, or any combinations thereof.

In addition to propylene or other suitable carbon containing precursor, the process may employ an inert or chemically unreactive gas such as argon, helium, nitrogen, or a combination of any of these.

Conventional processes may produce amorphous carbon layers with high amounts of hydrogen. The presence of hydrogen generally decreases the etch selectivity of the AHM. While higher temperature depositions may decrease the hydrogen content, the modulus and hardness may be adversely affected, decreasing etch selectivity.

Another method of decreasing hydrogen content is to co-flow halide-containing species. Adding certain reactants to the process gas, such as halide-containing species, may decrease the presence of hydrogen in the deposited film. Generally, the hydrocarbon precursors may be flowed into a plasma and form carbon ions and hydrogen ion and/or radicals, amongst other particles. The hydrogen radicals or ions may interact with carbon atoms depositing on the surface of the hardmask, incorporating hydrogen into the deposited film and even removing deposited carbon from the film, resulting in an etch process that decreases deposition rate.

Without being bound by theory, it is believed that halide-containing species, such as SF₆, may react with the hydrocarbon precursors and/or hydrogen radicals formed during the deposition process to form SF₅ and HF, which may be exhausted from the processing chamber without etching the hardmask. The production of HF reduces the presence of hydrogen radicals, inhibiting the competing etch process and thus increasing the overall rate of deposition. Other halide-containing species that react with hydrogen radicals and/or ions may also be used, such as CF₄.

While flowing a halide-containing species may reduce the hydrogen content of the AHM, the halide-containing species may deposit in the film as impurities and the mechanical properties of the film are also typically reduced, e.g., lower modulus and hardness. The reduction in modulus and hardness, as well as the presence of impurities from the halide-containing species, e.g., sulfur or fluorine, may reduce the etch selectivity of the film more than the reduction of hydrogen content improves etch selectivity. This net reduction in etch selectivity is undesirable.

To improve the mechanical properties of AHM, RF power may be controlled. AHM films may be deposited using a PECVD process where a plasma is ignited using low frequency (LF) power and high frequency (HF) power. Pulsing the LF power may allow for ions to bombard the surface when the LF power is on, increasing density, while allowing the ions to form a more ordered structure with less stress when the LF power is off, reducing stress. This increase in density while reducing stress may improve the mechanical properties of the film, in particular hardness and modulus. The LF power may be characterized by a duty cycle. As illustrated and known in the art, a duty cycle (DC) is defined by the equation DC=tₒₙ/(tₒₙ+t_{off}), and represents the percentage of time that the power is on, or set at high power. Duty cycle and pulse frequency together can be used to determine the time that LF power is on, i.e. a 100 Hz pulse frequency with a duty cycle of 25% indicates that the LF power is on for 2.5 ms, and off for 7.5 ms. The HF power may be maintained as unpulsed (“constant”) while the LF power is pulsed.

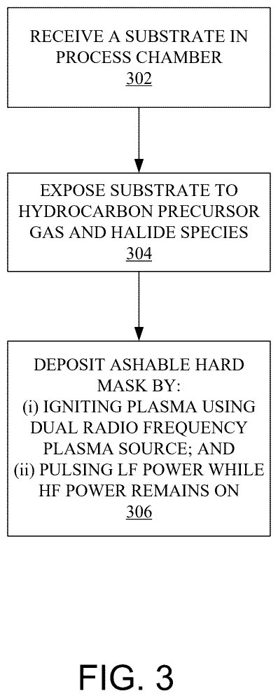

FIG. 3 shows a process flow diagram showing relevant operations of methods of forming AHMs by modulating dual RF plasma power according to various examples. In operation 302 a substrate is received in a processing chamber. The substrate may be provided to the chamber in this operation, or the substrate may already be in the chamber from a prior operation. In operation 304 the substrate is exposed to a process gas including a hydrocarbon precursor and a halide-containing species. In addition to hydrocarbon precursors, an inert gas carrier may be used. The inert gas may include helium (He), argon (Ar), nitrogen (N₂), hydrogen (H₂), or a combination of any of these.

Next, in operation 306, an ashable hardmask is deposited on the substrate by a PECVD process by igniting plasma using a dual RF plasma source to produce a plasma having a pulsed low frequency (LF) component and a high frequency (HF) component. The pulsed LF component may be produced by pulsing a LF power source. In some examples, pulsing the LF RF power includes using a high power, fast pulse, and low duty cycle to generate a high peak energy ion bombardment with a low mean ion density. In some examples, flowing the halide-containing species may be performed after the plasma is ignited. The halide-containing species may act as an etchant for the hardmask or other materials in the processing chamber. Thus, flowing the halide-containing species after igniting the plasma may inhibit any etch process, as the halide-containing species may instead react with the ions and radicals formed from the hydrocarbon precursor flowed into the plasma.

The result of operation 306 is an AHM film. This process produces a film with better density to stress ratio and higher selectivity. Depending on the duty cycle of the LF power, the pulsing frequency may be adjusted to maintain a high mean ion energy, while altering the mean ion density. In some examples the duty cycle may be decreased to produce a low modulus, low stress, film. In other examples, duty cycle may be increased to produce a high modulus, high stress, film. Increasing duty cycle may also increase the deposition rate of the AHM film. Both types of films may be desirable depending on other process conditions.

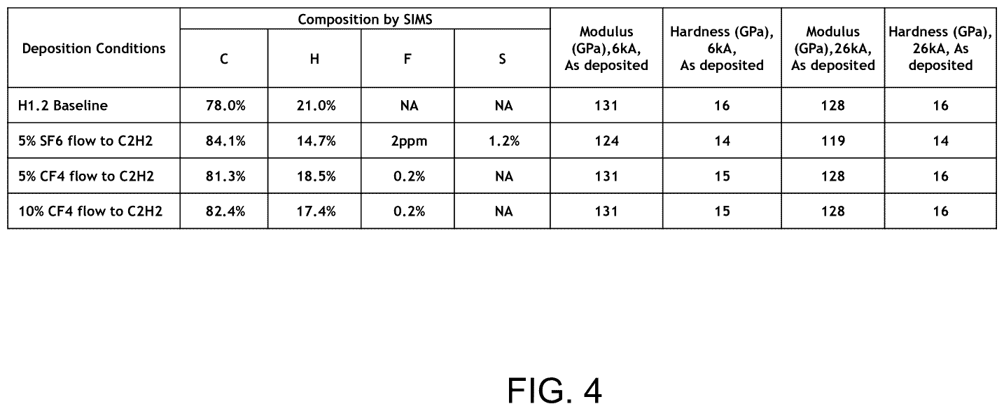

FIG. 4 presents a table illustrating the effect of SF₆ and CF₄ on various film properties when included in the process gas, as well as a film deposited without any flow of halide-containing species. As shown in FIG. 4, increasing the flow of SF₆ to 5% of the flow of C₂H₂ decreased the hydrogen content of the resulting AHM from about 21% to about 14.7%. Similar decreases in hydrogen content were found coflowing CF₄. Notably, the modulus and hardness of the resulting films are relatively similar to the modulus and hardness of the baseline film flowed without a halide-containing species. Coflowing SF₆ resulted in a greater decrease in hydrogen content than CF₄, but also a greater decrease in modulus and hardness (though the overall decrease in modulus and hardness is still limited). Conversely, coflowing CF₄ would not decrease hydrogen content as much as SF₆, but the modulus and hardness values were closer to the film deposited without coflowing halide-containing species.

Other process conditions for all deposited films of shown in FIG. 4 include: pedestal temperature of 250° C., pressure of 0.5 Torr, flow of 125 sccm C₂H₂, 4500 W at 13.56 MHz, and 600 W at 400 kHz with a 62% Duty Cycle.

High aspect ratio patterning uses AHMs having high etch selectivity. Etch selectivity can be determined by comparing the etch rate of the AHM layer to an underlying layer. The etch selectivity can sometimes be approximated by determining the hydrogen content, refractive index (RI), density, and Young's modulus, or rigidity, of the AHM layer. Typically, lower hydrogen content, higher RI, higher density, and higher modulus, or a more rigid, AHM is able to withstand higher etch rates in an etch process involving more ion bombardment. Therefore, AHMs with lower hydrogen content, higher RI, higher density, and/or higher modulus have higher selectivity and lower etching rate and can be used more efficiently and effectively for processing high aspect ratio semiconductor processes. The desired etch selectivity of the AHM may depend on the etching process and the composition of the underlying layers, but the correlation between etch selectivity and the material properties above may remain the same regardless of the etching process or composition of the underlying layers. The selectivity correlations as described here applies to all types of underlying layers, including polysilicon layers, oxide layers, and nitride layers.

AHM films produced in accordance with the disclosed methods are typically composed primarily of carbon and hydrogen, but other elements may be present in the film. In some examples the carbon concentration is at least about 70 percent atomic. Examples of other elements that may be present in the AHM film include halogens, nitrogen, sulfur, boron, oxygen, tungsten, titanium, and aluminum. Typically, such other elements are present in amounts not greater than about 10 percent atomic. In some examples, the hydrogen concentration is less than about 20% atomic, less than about 18% atomic, or less than about 15% atomic.

Notably, flowing a lower amount of halide-containing species, e.g., less than about 20% or less than about 15% of the flow of hydrocarbons, may significantly decrease the amount of hydrogen without degrading mechanical properties when the LF power is pulsed during deposition. In some examples, a coflow of halide-containing species as low as 5% may significantly reduce hydrogen content without impacting mechanical properties. This may lead to a net increase in etch selectivity of the resulting film.

The deposited amorphous carbon layer should have a relatively high density. In certain examples, an amorphous carbon layer has a density of about 1.65 to about 1.85 g/cm3. In certain examples, an amorphous carbon layer has a hardness of at least about 14 GPa, or between about 14 and about 16 GPa.

While density is defined in units of mass per volume, direct measurements of density are not always easily available. However, in some cases, more easily measurable properties may serve as a proxy for density. One such property is modulus. In some examples, an amorphous carbon layer has a modulus of at least about 120 GPa, or between about 120 and about 135 GPa.

In certain examples, an amorphous carbon layer has a relatively high content of graphite-like carbon in comparison to diamond-like carbon. It should have relatively high bond content of sp² bonds in comparison to sp³ bonds. In certain examples, an amorphous carbon layer has an sp² content of about 5% to about 30% or about 10% to about 15%, with the rest of the amorphous carbon layer having diamond-like sp³ bonds.

In various examples, a halide-containing species is added to the process gas during deposition of an amorphous carbon film. In some examples, the halide-containing species is a fluorine-containing species and/or a chlorine-containing species. In some examples, the halide-containing species is sulfur hexafluoride. In some examples, the halide-containing species is carbon tetrafluoride. In certain examples, a deposition process includes a halide-containing species at a volumetric (approximately molar) flow rate of about 1% to about 20% a flow rate of a hydrocarbon precursor. In certain examples, a deposition process includes a halide-containing species at a flow rate of about 5% to about 15% a flow rate of a hydrocarbon precursor.

In certain examples, a deposition process includes an inert or chemically unreactive gas (e.g., Ar, He, and/or N₂) at a molar flow rate of about 5 slm.

In certain examples, the deposition process gas has about 3% to about 50% acetylene or other hydrocarbon precursor, about 1% to about 20% sulfur hexafluoride or other halide-containing species, and about 25% to about 96% inert or chemically unreactive gas. All percentages are by volume or molar. In certain examples, the deposition process gas has about 15% to about 25% acetylene or other hydrocarbon precursor, about 5% to about 15% halide-containing species, and about 70% to about 80% inert or chemically unreactive gas. In certain examples, the inert or chemically unreactive gas is argon, nitrogen, and/or helium. Percentage values are based on volumetric flow rates.

In some examples, the process gas consists of acetylene and/or other carbon-containing precursors, inert gas, and SF₆ or CF₄. In some examples, the process gas consists essentially of acetylene and/or other carbon-containing precursors, inert gas, and halide-containing species. In some examples, the flow rate of the hydrocarbon precursors is between about 100 sccm and about 200 sccm. In further examples, the process gas can comprise acetylene and/or other carbon-containing precursors, inert gas, and halide-containing species, as well as one or more other species.

In some examples, the hydrocarbon precursor is one defined by the formula CₓH_{y}, wherein X is an integer between 2 and 10, and Y is an integer between 2 and 24. Examples include methane (CH₄), acetylene (C₂H₂), ethylene (C₂H₄), propylene (C₃H₆), butane (C₄H₁₀), cyclohexane (C₆H₁₂), benzene (C₆H₆), and toluene (C₇H₈). In certain examples, the process gas includes propylene alone or optionally in combination with one or more additional hydrocarbon precursors. In certain examples the hydrocarbon precursor is a halogenated hydrocarbon, where one or more hydrogen atoms are replaced by a halogen, particularly fluorine, chlorine, bromine, and/or iodine. In some examples the hydrocarbon precursor has a ratio of C:H of at least 1:2. In some examples, two or more hydrocarbon precursors may be used.

While the specification primarily identifies SF₆ and CF₄ as coflowed halide-containing species for AHM films, in some examples, the process gas may include one or more of: hypervalent phosphorous chlorides or fluorides (e.g., PCl₅ or PF₅), or xenon fluoride (e.g., XeF₂, XeF₄, XeF₆). In some examples, a halide-containing species is selected from the group consisting of SF₆, CF₄, hypervalent phosphorous chlorides or fluorides, xenon fluorides, and any combinations thereof. In some examples, a halide-containing species reacts with hydrogen ions and/or radicals during deposition of an AHM film. The halide-containing species may reduce hydrogen content as described herein while not substantially depositing any species in the AHM film.

In some examples, the pressure in the processing chamber may be about 0.1 to about 15 Torr, about 0.5 Torr to about 5 Torr, or about 1 Torr. In some examples, the high frequency (“HF,” e.g., 13.56 MHz power) may be about 50 W to about 8000 W, at least about 350 W, about 400 W to about 4000 W, or about 6000 W, for a four station configuration. In some examples, the low frequency (“LF,” e.g., 400 kHz power) may be about 0 to about 6000 W, about 900 to about 4000 W, or about 3450 W, for a four-station configuration. In some examples, the LF power may be pulsed according to a duty cycle. In some examples, the duty cycle may be between about 10% and about 75%, at least about 10%, at least about 25%, at least about 50%, between about 50% and about 75%, or about 60%.

It has been observed in other contexts that the higher the deposition temperature, the less hydrogen present in the amorphous carbon film. Because lower amounts of hydrogen are desirable for hardmask applications, the temperature is often increased. However, higher temperatures will adversely lower modulus and hardness, which is undesirable. In some examples, the pedestal temperature may be about 20° C. to about 750° C., or at most about 650° C., or about 550° C. to about 650° C., or about 650° C. In certain examples, it is at least about 200° C., or at least about 250° C. In certain examples, it is at least about 500° C. In some examples, the pedestal temperature is at least about 150° C. or between about 150° C. and about 550° C. It has been observed that temperatures much higher than 650° C. may produce undesirable plasma results such as arcing in the chamber or degrade underlying films.

The film deposited for should be relatively uniform over the face of the wafer. The relative amount of uniformity or nonuniformity in the deposited film is a strong function of the process conditions used to deposit the amorphous carbon layer, rather than necessarily an intrinsic property of the amorphous carbon layer's composition.

While not wishing to be bound by theory, it is believed that hydrogen content and other impurities decrease the etch selectivity of amorphous carbon films. Thus, reducing hydrogen content may improve the etch selectivity of an amorphous carbon film. Halide-containing species impacts hydrogen content of AHM films. It appears to react with hydrogen in the plasma and form hydrogen halides that do not etch the growing film. For example, HF is not considered a depositing species as fluorine is not found in the resulting film by RBS or solid state FTIR in significant amounts. Therefore, the presence of halide-containing species may reduce the hydrogen content of films.

Somewhat surprisingly in this regard, it has been found that the halide-containing species do not themselves etch or at least significantly etch the depositing amorphous carbon film. Sulfur hexafluoride, for example, is widely used as an etchant gas in the integrated circuit fabrication industry. Surprisingly, it has been found that in the absence of a depositing carbon layer, sulfur hexafluoride and propylene, a hydrocarbon, react to form carbon hexafluoride. This result might suggest that sulfur hexafluoride, which is a widely used etchant gas, would react with the forming amorphous carbon hardmask and etch it. However, this is not the case. Instead, a small ratio, e.g., ratios as described herein, of Sulfur hexafluoride or other halide-containing species may reduce hydrogen content of the film without etching or with significantly reduce etching of the carbon hardmask. Furthermore, as shown in FIG. 4, above, the mechanical properties of films deposited using a process gas including a halide-containing species may be significantly similar to the mechanical properties of films deposited without such halide-containing species.

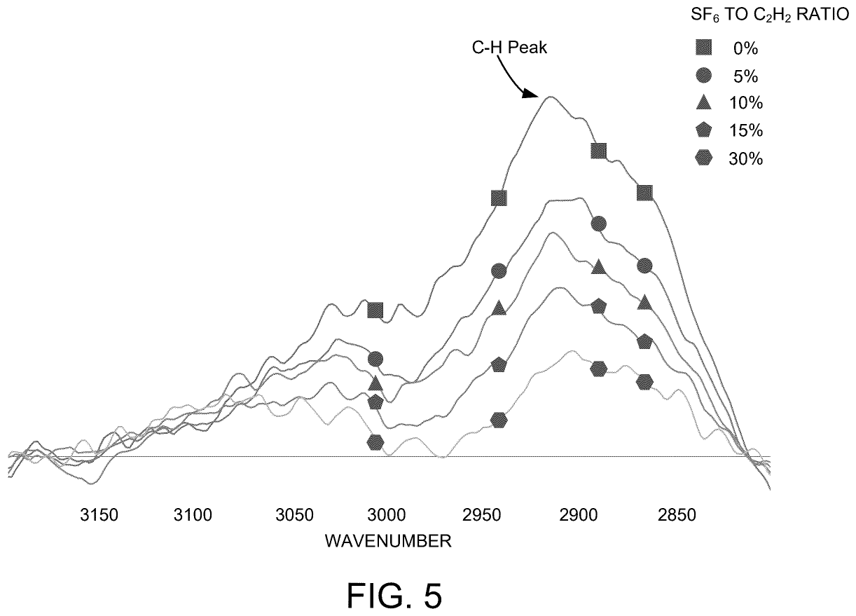

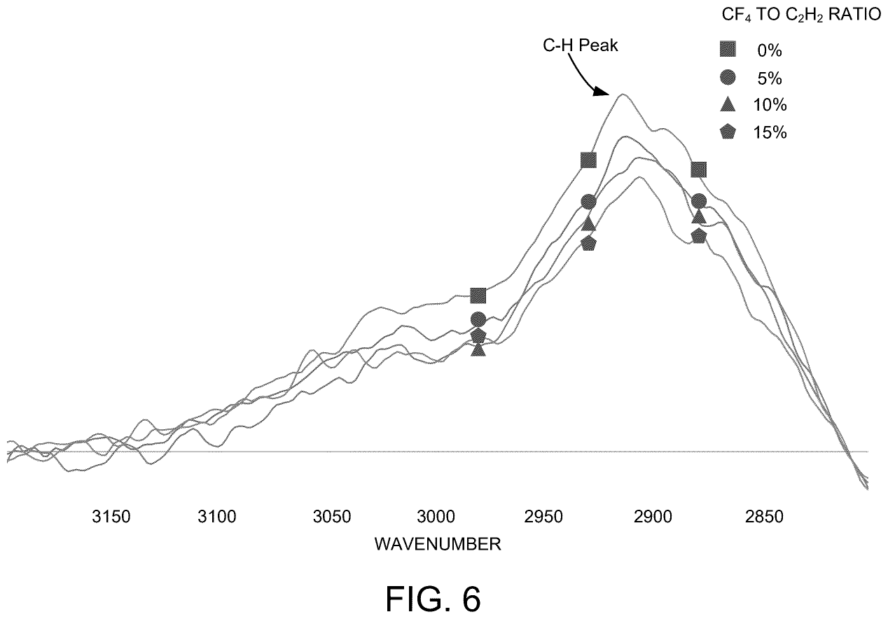

In some examples, a relatively small amount of halide-containing species may significantly reduce hydrogen content. FIGS. 5 and 6 present FTIR spectra for various ratios of SF₆ to C₂H₂ (FIG. 5) and various ratios of CF₄ to C₂H₂ (FIG. 5). As shown in FIG. 5, a co-flow of SF₆ that is as little as 5% of the flow of C₂H₂ may significantly reduce a C—H peak around 2925, indicating reduced hydrogen content in the film. This peak is further reduced with higher amounts of SF₆, though higher amounts may lead to greater incorporation of sulfur and fluorine in the film. FIG. 6, similarly, illustrates a reduced C—H peak with as little as 5% CF₄ added to the process gas flow.

Examples can be implemented in a plasma enhanced chemical vapor deposition (PECVD) reactor. Such a reactor may take many different forms. Further, various examples may be implemented on a multi-station or single station tool.

Generally, the apparatus will include one or more chambers or reactors that each include one or more stations. Chambers will house one or more wafers and are suitable for wafer processing. The one or more chambers maintain the wafer in a defined position or positions, by preventing rotation, vibration, or other agitation. In some example, a wafer undergoing AHM deposition is transferred from one station to another within a chamber during the process. For example, a 2000 Å AHM deposition may occur entirely at one station, or 500 Å of film may be deposited at each of four stations in accordance with various examples. Alternatively, any other fraction of the total film thickness may be deposited at any number of stations. In various examples where more than one AHM is deposited, more than one station may be used to deposit each AHM layer. During processing, each wafer is held in place by a pedestal, wafer chuck, and/or other wafer holding apparatus. For certain operations where the wafer is to be heated, the apparatus may include a heater such as a heating plate.

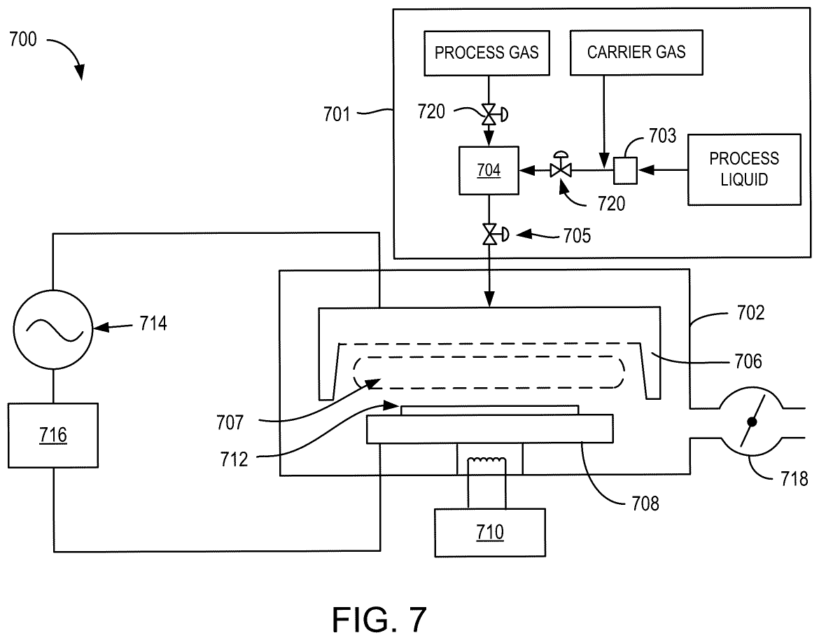

FIG. 7 schematically shows an example of a process station 700 that may be used to deposit material using plasma enhanced chemical vapor deposition (PECVD). For simplicity, the process station 700 is depicted as a standalone process station having a processing chamber body 702 for maintaining a low-pressure environment. However, it will be appreciated that a plurality of process stations 700 may be included in a common processing tool environment. Further, it will be appreciated that, in some examples, one or more hardware parameters of process station 700, including those discussed in detail below, may be adjusted programmatically by one or more computer controllers.

Process station 700 fluidly communicates with reactant delivery system 701 for delivering process gases to a distribution showerhead 706. Reactant delivery system 701 includes a mixing vessel 704 for blending and/or conditioning process gases for delivery to showerhead 706. One or more mixing vessel inlet valves 720 may control introduction of process gases to mixing vessel 704. Similarly, a showerhead inlet valve 705 may control introduction of process gasses to the showerhead 706.

For example, the example of FIG. 7 includes a vaporization point 703 for vaporizing liquid reactant to be supplied to mixing vessel 704. In some examples, vaporization point 703 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some examples, delivery piping downstream of vaporization point 703 may be heat traced. In some examples, mixing vessel 704 may also be heat traced. In one non-limiting example, piping downstream of vaporization point 703 has an increasing temperature profile extending from approximately 100° C. to approximately 150° C. at mixing vessel 704.

In some examples, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 703. In one scenario, a liquid injector may be mounted directly to mixing vessel 704. In another scenario, a liquid injector may be mounted directly to showerhead 706.

In some examples, a liquid flow controller upstream of vaporization point 703 may be provided for controlling a mass flow of liquid for vaporization and delivery to process station 700. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some examples, the LFC may be dynamically switched between a feedback control mode and a direct control mode. In some examples, the LFC may be dynamically switched from a feedback control mode to a direct control mode by disabling a sense tube of the LFC and the PID controller.

Showerhead 706 distributes process gases toward substrate 712. In the example shown in FIG. 7, substrate 712 is located beneath showerhead 706, and is shown resting on a pedestal 708. It will be appreciated that showerhead 706 may have any suitable shape, and may have any suitable number and arrangement of ports for distributing processes gases to substrate 712.

In some examples, a microvolume 707 is located beneath showerhead 706. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some examples, pedestal 708 may be raised or lowered to expose substrate 712 to microvolume 707 and/or to vary a volume of microvolume 707. For example, in a substrate transfer phase, pedestal 708 may be lowered to allow substrate 712 to be loaded onto pedestal 708. During a deposition process phase, pedestal 708 may be raised to position substrate 712 within microvolume 707. In some examples, microvolume 707 may completely enclose substrate 712 as well as a portion of pedestal 708 to create a region of high flow impedance during a deposition process.

Optionally, pedestal 708 may be lowered and/or raised during portions the deposition process to modulate process pressure, reactant concentration, etc., within microvolume 707. In one scenario where processing chamber body 702 remains at a base pressure during the deposition process, lowering pedestal 708 may allow microvolume 707 to be evacuated. Example ratios of microvolume to processing chamber volume include, but are not limited to, volume ratios between 1:700 and 1:10. It will be appreciated that, in some examples, pedestal height may be adjusted programmatically by a suitable computer controller.

In another scenario, adjusting a height of pedestal 708 may allow a plasma density to be varied during plasma activation and/or treatment cycles included in the deposition process. At the conclusion of the deposition process phase, pedestal 708 may be lowered during another substrate transfer phase to allow removal of substrate 712 from pedestal 708.

While the example microvolume variations described herein refer to a height-adjustable pedestal, it will be appreciated that, in some examples, a position of showerhead 706 may be adjusted relative to pedestal 708 to vary a volume of microvolume 707. Further, it will be appreciated that a vertical position of pedestal 708 and/or showerhead 706 may be varied by any suitable mechanism within the scope of the present disclosure. In some examples, pedestal 708 may include a rotational axis for rotating an orientation of substrate 712. It will be appreciated that, in some examples, one or more of these example adjustments may be performed programmatically by one or more suitable computer controllers.

Returning to the example shown in FIG. 7, showerhead 706 and pedestal 708 electrically communicate with RF power supply 714 and matching network 716 for powering a plasma. In some examples, the plasma energy may be controlled by controlling one or more of a process station pressure, a gas concentration, an RF source power, an RF source frequency, and a plasma power pulse timing. For example, RF power supply 714 and matching network 716 may be operated at any suitable power to form a plasma having a desired composition of radical species. Examples of suitable powers are included above. Likewise, RF power supply 714 may provide RF power of any suitable frequency. In some examples, RF power supply 714 may be configured to control high-and low-frequency RF power sources independently of one another. Example low-frequency RF frequencies may include, but are not limited to, frequencies between 50 kHz and 700 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some examples, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some examples, one or more plasma parameters may be programmatically adjusted based on measurements from such in-situ plasma monitors. For example, an OES sensor may be used in a feedback loop for providing programmatic control of plasma power. It will be appreciated that, in some examples, other monitors may be used to monitor the plasma and other process characteristics. Such monitors may include, but are not limited to, infrared (IR) monitors, acoustic monitors, and pressure transducers.

In some examples, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some examples, instructions for setting one or more plasma parameters may be included in a recipe phase preceding a plasma process phase. For example, a first recipe phase may include instructions for setting a flow rate of an inert and/or a hydrocarbon precursor gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some examples, pedestal 708 may be temperature controlled via heater 710. Further, in some examples, pressure control for deposition process station 700 may be provided by butterfly valve 718. As shown in the example of FIG. 7, butterfly valve 718 throttles a vacuum provided by a downstream vacuum pump (not shown). However, in some examples, pressure control of process station 700 may also be adjusted by varying a flow rate of one or more gases introduced to process station 700.

Stacks of alternating layers of materials used in forming three-dimensional (3D) integrated circuits, such as those described above, can also be referred to as mold stacks. Example mold stacks include ONON (silicon oxide-silicon nitride) stacks and OPOP (silicon oxide-polycrystalline silicon (polysilicon)) stacks. An intermediate step in a 3D memory fabrication process can comprise etching high aspect ratio (HAR) structures in a 3D memory mold stack using a directional etching process such as reactive ion etching (RIE). A carbon hardmask can be employed during the directional etching process to protect surrounding substrate surfaces.

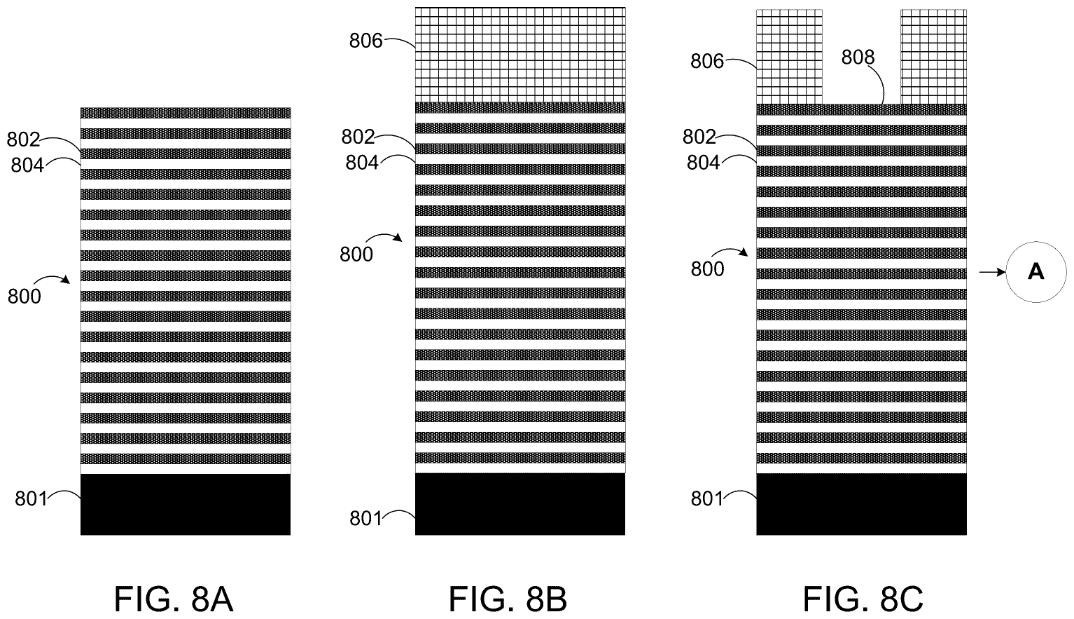

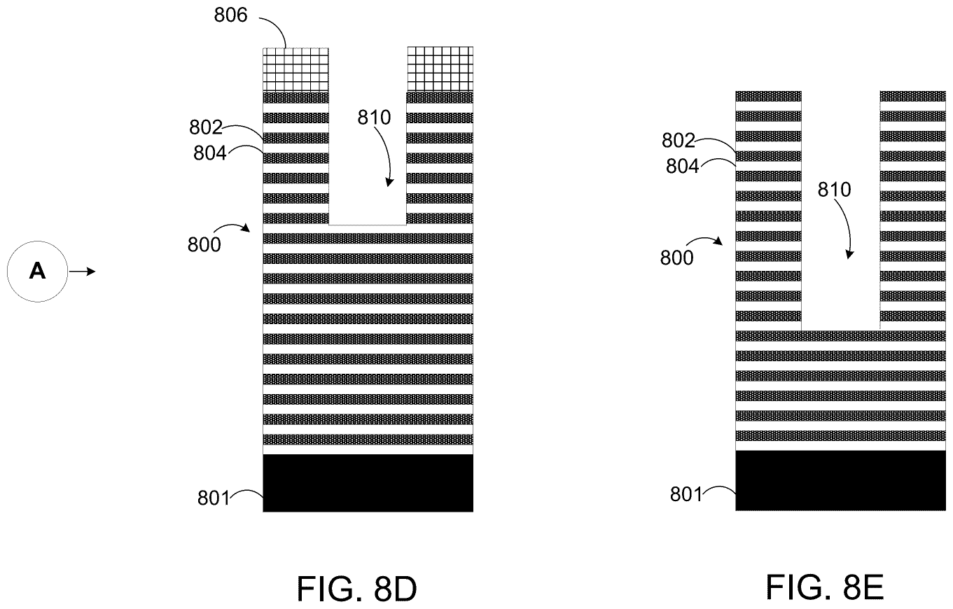

As the HAR feature etching process can require etching though a relatively large number of material layers, there is a risk that a carbon hardmask with insufficient etch selectively is fully consumed prior to completing the HAR feature etching process. FIGS. 8A-8E illustrate structures formed an example process for etching a 3D memory mold stack utilizing a carbon hardmask with insufficient etch selectivity. First, FIG. 8A shows a mold stack 800 formed on a substrate 801. The mold stack 800 comprises alternating layers of a first material 802 and a second material 804. As mentioned above, in some examples, the first material 802 can comprise silicon oxide and the second material 804 can comprise silicon nitride. In other examples, the first material 802 can comprise silicon oxide and the second material 804 can comprise polysilicon. In further examples, the first material 802 and the second material 804 can comprise any other suitable pair of materials.

FIG. 8B shows the mold stack 800 after deposition of a carbon hardmask 806. Any suitable deposition process can be used to deposit the carbon hardmask 806. Examples deposition processes include TCVD, PECVD and RPECVD. A carbon hardmask can be deposited by exposing a substrate to a carbon-containing precursor in an inert or reducing environment. Example carbon-containing precursors include can include alkanes having a general formula CₙH₂ₙ₊₂, where n is an integer in a range of 1 to 10 (such as methane, ethane, etc.), alkenes having a general formula CₙH₂ₙ where n=2 to 10 (such as ethylene, propylene, etc.), and alkynes having a general formula CₙH₂ₙ₋₂ where n=2 to 10 (such as acetylene, propyne, etc.), that are gas-phase under processing conditions. Other examples of carbon-containing precursors can comprise aliphatic and aromatic cyclic hydrocarbons, nitrogen- containing compounds including alkyl amines, and oxygen-containing compounds including alcohols, ketones, esters, aldehydes, and ethers, that are gas-phase under processing conditions.

Next, FIG. 8C shows the carbon hardmask 806 after the carbon hardmask 806 has been patterned. For example, the carbon hardmask 806 can be patterned by photolithography, followed by an oxidative etch. The patterning process removes the hardmask from a region 808 of the mold stack 800 in which a HAR feature is to be etched using a directional etching process. Example directional etching processes include sputtering, ion milling and reactive ion etching (RIE).

During the directional etching process, the carbon hardmask 806 also is consumed. A rate at which the carbon hardmask 806 is consumed during the directional etching etch depends upon the selectivity of the carbon hardmask 806. FIG. 8D shows the mold stack 800 after performing a portion of the directional etch process. As can be seen, the thickness of the carbon hardmask 806 has been reduced compared to FIG. 8C.

In case of a carbon hardmask with insufficient etch selectivity, the entire carbon hardmask may be consumed before the HAR feature etching process has been completed. FIG. 8E shows that the HAR feature 808 is etched only partway through the mold stack 800, while the carbon hardmask is 806 completely consumed. After the consumption of the carbon hardmask 806, the underlying layers of the mold stack are exposed and are subject to damage from the etching process.

As one possible solution to the problem illustrated in FIGS. 8A-8E, a thicker carbon hardmask may be deposited. However, a patterning process can impose limitations on the thickness of the carbon hardmask. For example, a carbon hardmask that is too thick can distort the feature profile and shape during the patterning process. Further, a thicker carbon hardmask can induce a greater degree of curvature in a substrate than a thinner carbon hardmask due to stress. The curvature can degrade feature sizes and shapes during the patterning process. In addition, a thicker carbon hardmask is more likely to crack than a thinner hardmask. The mechanical strength of the carbon hardmask can be characterized by its modulus of elasticity. The etch selectivity, stress, mechanical strength, and the overall thickness of the carbon hardmask layer can determine the highest aspect ratio structures that can be etched using a given carbon hardmask.

In view of the above challenges, examples are disclosed that relate to the use of annealed carbon hardmasks. The disclosed annealed carbon hardmasks can provide higher mechanical strength, higher etch selectivity and lower stress than unannealed carbon hardmasks of equal thickness. One example provides a method of processing a substrate comprising a carbon hardmask on a 3D memory mold stack. The method comprises placing a substrate in an annealing tool. The carbon hardmask has a first stress and a first hydrogen content. The method further comprises annealing the substrate to form an annealed carbon hardmask having a second stress and a second hydrogen content. The second stress is lower than the first stress. The terms “lower” and “higher” indicate a magnitude of stress, wherein a “lower” stress after annealing has a lower absolute value than a “higher” stress before annealing. Further, the second hydrogen content is lower than the first hydrogen content. After annealing, the annealed carbon hardmask can be used for etching higher aspect ratio features than an unannealed carbon hardmask of a same thickness.

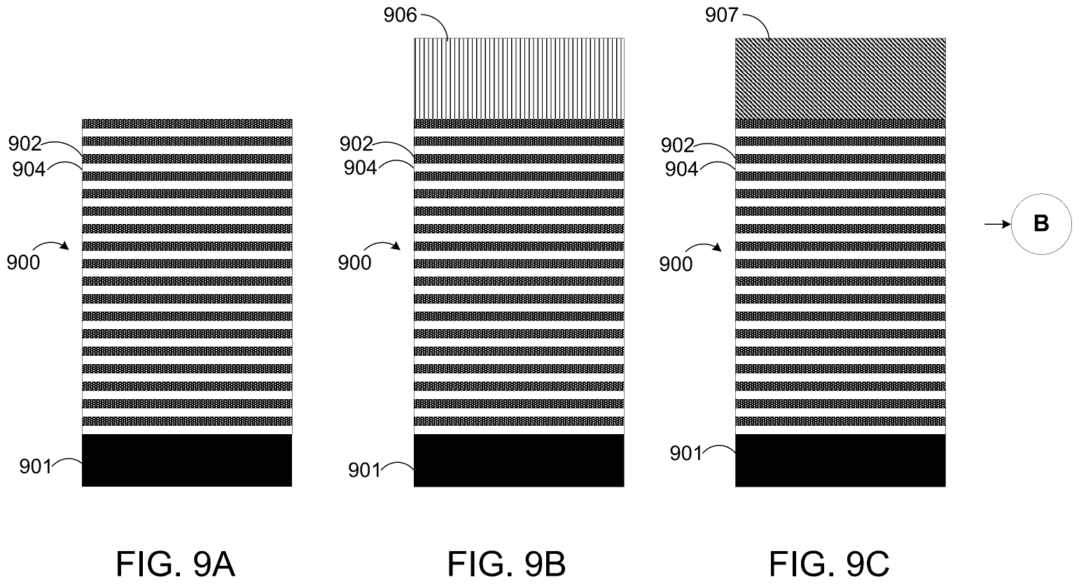

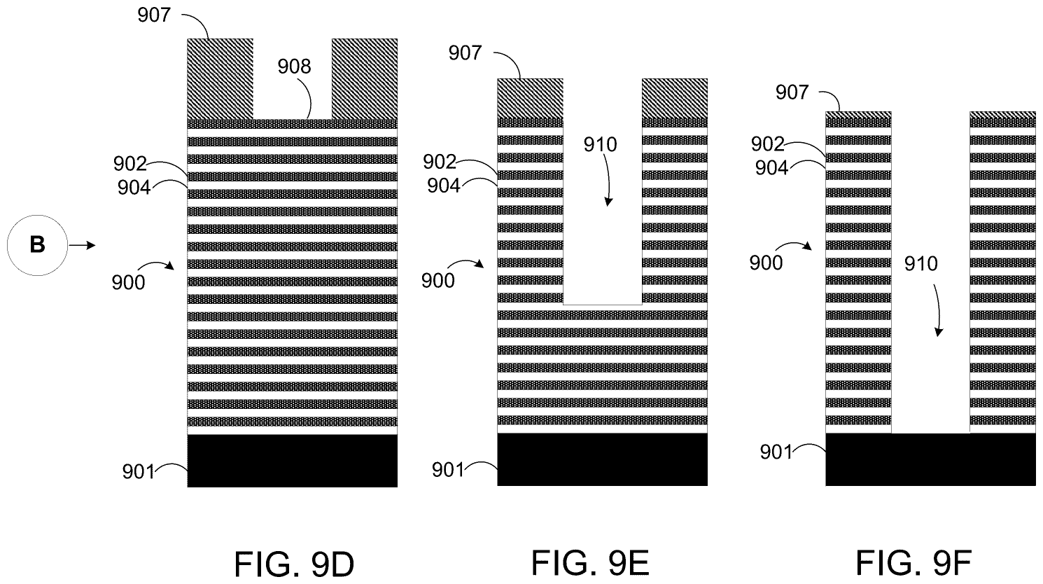

FIGS. 9A-9E schematically show structures formed in an example mold stack etching process using an annealed carbon hardmask. FIG. 9A shows a mold stack 900 formed on a substrate 901. The mold stack 900 comprises alternating layers of a first material 902 and a second material 904. As mentioned above, in some examples, the first material 902 can comprise silicon oxide and the second material 204 can comprise silicon nitride. In other examples, the first material 902 can comprise silicon oxide and the second material 904 can comprise polysilicon. In further examples, the first material 902 and the second material 904 can comprise any other suitable pair of materials.

FIG. 9B shows a carbon hardmask 906 deposited on the top of the mold stack 900. As mentioned above, any suitable deposition process can be used to deposit the carbon hardmask. Examples include thermal CVD, PECVD or RPECVD. Suitable carbon-containing precursors for depositing the carbon hardmask 906 can include alkanes having a general formula CₙH₂ₙ₊₂ where n is an integer in a range of 1 to 10 (such as methane, ethane, etc.), alkenes having a general formula CₙH₂ₙ where n=2 to 10 (such as ethylene, propylene, etc.), and alkynes having a general formula CₙH₂ₙ₋₂ where n=2 to 10 (such as acetylene, propyne, etc.), that are gas-phase under processing conditions. Other examples of carbon-containing precursors can comprise aliphatic and aromatic cyclic hydrocarbons, nitrogen-containing compounds including alkyl amines, and oxygen-containing compounds including alcohols, ketones, esters, aldehydes, and ethers, that are gas-phase under processing conditions. Other gases that can be used during the deposition include inert gases such as argon or helium. Further, in some examples, hydrogen and/or nitrogen can be used.

After depositing the carbon hardmask 906, the carbon hardmask 906 is annealed. FIG. 9C shows that the carbon hardmask 906 has been converted to an annealed carbon hardmask 907 by annealing. The annealed carbon hardmask 907 can have a lower stress and a lower hydrogen content than the carbon hardmask 906 prior to annealing. Annealing can be performed under any suitable conditions. In some examples, the carbon hardmask can be annealed at a temperature within a range of 500-1000° C. Likewise, annealing can be performed under any suitable gaseous environment. In some examples, the annealing is performed under an inert gaseous environment. Example inert gases include helium, neon, argon, krypton, xenon, and nitrogen. The annealing can be performed at atmospheric pressure, or at pressures lower or higher than atmospheric pressure.

The carbon hardmask 906 before annealing has a first stress and a first hydrogen content. Annealing drives hydrogen from the carbon hardmask to produce an annealed carbon hardmask with a second stress and a second hydrogen content. The second stress is lower than the first stress. The second hydrogen content is lower than the first hydrogen content. As hydrogen-carbon bonds are terminal bonds, the presence of hydrogen-carbon bonds can shift carbon-carbon bond angles in the carbon hardmask. The shifted bond angles can lead to stress and resulting strain. Thus, driving hydrogen from the carbon hardmask 906 to form the annealed carbon hardmask 907 can provide for lower stress in the annealed carbon hardmask 907 compared to the carbon hardmask 906. Further, driving hydrogen from the carbon hardmask 906 can also help to increase a modulus of the annealed carbon hardmask 907 compared to the carbon hardmask 906 prior to annealing. This may be because removing hydrogen from a carbon hardmask allows for more carbon-carbon bonding to be formed. This can improve the etch selectivity of the annealed carbon hardmask 907 compared to the carbon hardmask 906 prior to annealing.

In some examples, the stress in an annealed carbon hardmask can be greater than or equal to 1 MPa and less than or equal to 100 MPa. Further, in some examples, an annealed carbon hardmask can exhibit a modulus of elasticity greater than or equal to 60 GPa and less than or equal to 250 GPa after annealing. Additionally, in some examples, the second, lower hydrogen content can be less than or equal to 10 atomic percent. In other examples, an annealed carbon hardmask can have a stress, a modulus of elasticity, and/or a hydrogen content outside of these ranges.

In some examples, the annealing time and temperature can be controlled such that an annealed carbon hardmask exhibits a limited change in the grain size as measured by Raman spectroscopy compared to the carbon hardmask prior to annealing. In some examples, the change in an average grain size can be less than or equal to 15 percent after annealing. In addition, annealing can be controlled such that the annealed carbon hardmask exhibits a change in sp³ carbon content of less than or equal to 10 percent as measured by Raman spectroscopy.

Referring next to FIG. 9D, the annealed carbon hardmask 907 is patterned. In some examples, a photolithography process can be used. The patterning process removes the hardmask from the region 908. The remaining regions of the annealed carbon hardmask 907 protect underlying regions of the mold stack 900 from etching.

Referring next to FIG. 9E, a directional etching process is used to form a high aspect ratio feature 910. Any suitable method for directional etching can be used. As mentioned above, examples methods for directional etching include sputtering, ion milling and reactive ion etching (RIE). Comparing FIG. 9D and FIG. 9E, the thickness of the annealed carbon hardmask 907 from FIG. 9C is reduced during etching of high aspect ratio feature 910 as the annealed carbon hardmask 907 is consumed. However, the etch selectivity of the annealed carbon hardmask 907 of FIG. 9 is higher than that of the carbon hardmask 106 of FIG. 8. This allows directional etching to be continued without completely consuming the annealed carbon hardmask 907. Referring next to FIG. 9F, the high aspect ratio feature 910 has been completely etched without fully consuming the annealed carbon hardmask 907.

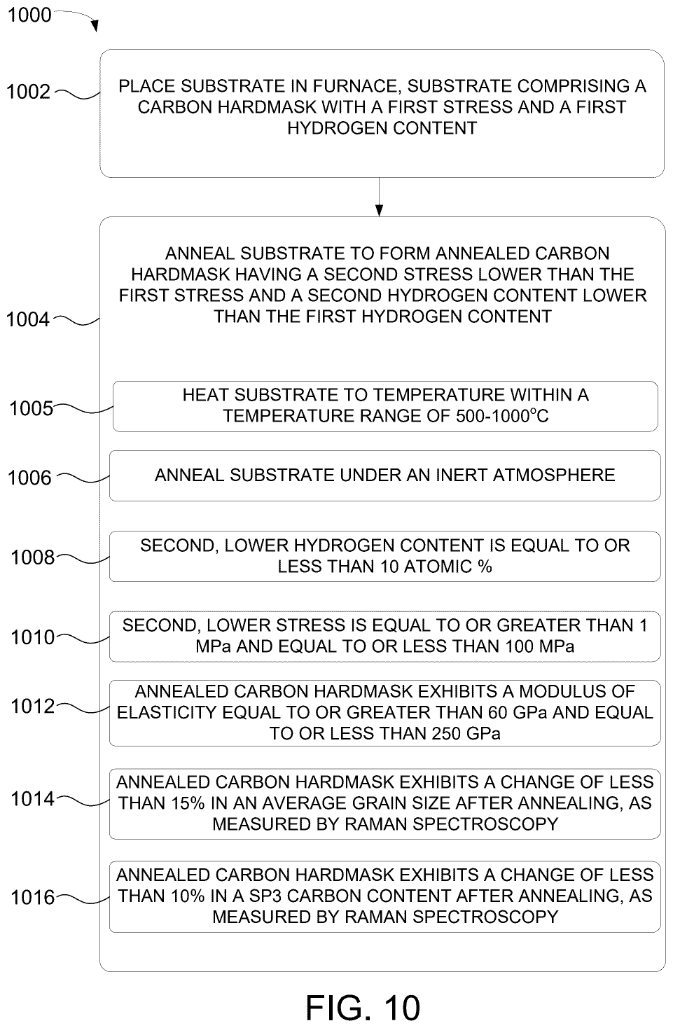

FIG. 10 shows a flow diagram depicting an example method 1000 for processing a substrate. Method 1000 comprises, at step 1002, placing a substrate in an annealing tool. The substrate comprises a carbon hardmask with a first stress and a first hydrogen content. Method 1000 further comprises, at step 1004, annealing the substrate to form an annealed hardmask. The annealed carbon hardmask has a second stress that is lower than the first stress. The annealed carbon hardmask also has a second hydrogen content that is lower than the first hydrogen content. Any suitable conditions can be used to anneal the carbon hardmask. In some examples, the substrate can be heated to a temperature within a temperature range of 500-1000° C., as indicated at 1005. In other examples, annealing can be performed at a temperature outside of this range. Further, the annealing can be performed in any suitable gaseous environment. In some examples, annealing can be performed under an inert atmosphere, as indicated at 1006. Examples of suitable gases to provide an inert atmosphere during annealing include helium, neon, argon, krypton, xenon, nitrogen, and mixtures of two or more thereof. In some examples, annealing can be performed using an annealing tool comprising an annealing chamber. In other examples, a reducing agent, such as hydrogen or ammonia, could be used. In other examples, annealing can be performed in another type of processing chamber. For example, annealing can be performed in a deposition chamber used to deposit the carbon hardmask.

The annealing process can drive hydrogen out of the carbon hardmask. In some examples, the second hydrogen content can have a value of less than or equal to 10 atomic percent, as indicated at 1008. Lowering of the hydrogen content in the carbon hardmask by annealing can result in the annealed carbon hardmask having a lower stress than the carbon hardmask prior to annealing. In some examples, the annealed carbon hardmask can have a stress greater than or equal to 1 MPa and less than or equal to 100 MPa, as indicated at 1010.

As mentioned above, the annealed carbon hardmask can have a greater amount of carbon-carbon bonding than the carbon hardmask prior to annealing. The lower hydrogen content, greater amount of carbon-carbon bonding, and lower stress of the annealed carbon hardmask compared to the carbon hardmask prior to annealing can give the annealed carbon hardmask a higher etch selectivity than the carbon hardmask prior to annealing. In some examples, the annealed carbon hardmask can exhibit a modulus of elasticity greater than or equal to 60 GPa and less than or equal to 250 GPa, as indicated at 1012. As discussed earlier, a higher modulus of elasticity can indicate a greater mechanical strength. Thus, the annealed carbon hardmask can be less prone to cracking at higher stress values and/or at greater thickness compared to the unannealed carbon hardmask.

The annealing time and temperature can be controlled such that the carbon hardmask exhibits a relatively small change in the grain size as measured by Raman spectroscopy. The change in an average grain size can be limited to a change less than or equal to 15% after annealing, as indicated at step 1014. In addition, annealing can be controlled such that the carbon hardmask exhibits a change in sp3 carbon content of less than or equal to 10% as measured by Raman spectroscopy, as indicated at step 1016.

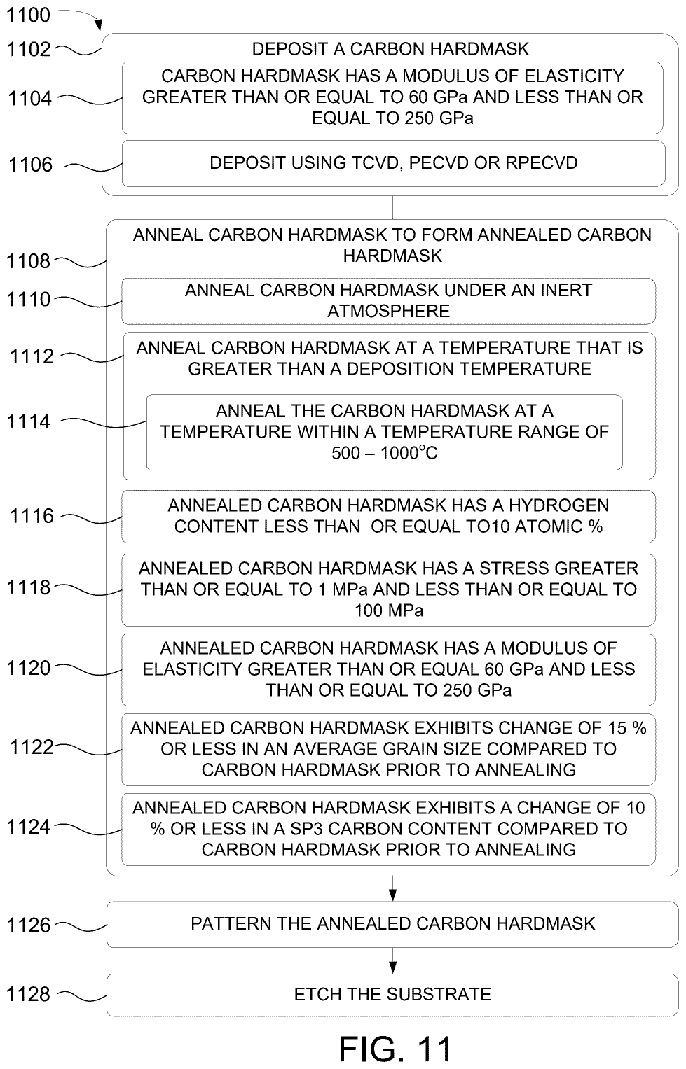

FIG. 11 shows a flow diagram depicting another example method for processing a substrate. The method 1100 comprises depositing a carbon hardmask at step 1102. In some examples, the deposition conditions can be controlled such that the carbon hardmask exhibits a modulus of elasticity greater than or equal to 60 GPa and less than or equal to 250 GPa, as indicated at step 1104. Deposition conditions that can be controlled include deposition temperature, total processing chamber pressure, partial pressure of a carbon-containing precursor. The carbon hardmask can be deposited using any suitable deposition method. Example deposition methods include TCVD, PECVD or RPECVD, as indicated at 1106. Where PECVD is used plasma power and plasma frequency used for carbon hardmask deposition also can be controlled. Example carbon-containing precursors include can include alkanes having a general formula CₙH₂ₙ₊₂, where n is an integer in a range of 1 to 10 (such as methane, ethane, etc.), alkenes having a general formula CₙH₂ₙ where n=2 to 10 (such as ethylene, propylene, etc.), and alkynes having a general formula CₙH₂ₙ₋₂ where n=2 to 10 (such as acetylene, propyne, etc.), that are gas-phase under processing conditions. Other examples of carbon-containing precursors can comprise aliphatic and aromatic cyclic hydrocarbons, nitrogen-containing compounds including alkyl amines, and oxygen-containing compounds including alcohols, ketones, esters, aldehydes, and ethers, that are gas-phase under processing conditions.

The method 1100 further comprises, at step 1108, annealing the carbon hardmask to form an annealed carbon hardmask. In some examples, annealing can be performed in an annealing tool. In other examples, annealing can be performed in another type of processing chamber. For example, the annealing can be performed in a deposition chamber used to deposit the carbon hardmask.

As mentioned above, annealing can be performed under any suitable gaseous environment. For example, the carbon hardmask can be annealed under an inert atmosphere, as indicated at 1110. In such examples, the annealing can be performed in an atmosphere comprising one or more of helium, neon, argon, krypton, xenon, or nitrogen. The annealing temperature can be greater than the deposition temperature of the carbon hardmask, as indicated at 1112. This can help remove hydrogen and allow carbon atoms to relax to a lower stress configuration after deposition. In some examples, annealing can be performed at a temperature within a temperature range of 500-1000° C., as indicated at 1114. In other examples, annealing can be performed at a temperature outside of this range. In some examples, annealing temperature and time can be controlled such that the hydrogen content in the annealed carbon hardmask is less than or equal to 10 atomic percent, as shown at 1116. The lower hydrogen content of the annealed carbon hardmask compared to the carbon hardmask prior to annealing can improve the etch selectivity of the annealed carbon hardmask relative to the carbon hardmask prior to annealing.

Further, as mentioned above, the lower hydrogen content in the annealed carbon hardmask compared to the hydrogen content in the carbon hardmask prior to annealing can provide for lower stress in the annealed carbon hardmask compared to the carbon hardmask prior to annealing. In some examples, the second stress can be greater than or equal to 1 MPa and less than or equal to 100 MPa, as indicated at 1118. Further, in some examples, the annealed carbon hardmask can exhibit a modulus of elasticity greater than or equal to 60 GPa and less than or equal to 250 GPa, as indicated at 1120. As discussed earlier, a higher modulus of elasticity can indicate a higher mechanical strength.

Further, an annealing time and temperature can be controlled such that the carbon hardmask exhibits a limited change in the grain size, as measured by Raman spectroscopy. In some examples, the annealed carbon hardmask can exhibit a change in an average grain size less than or equal to 15% compared to the carbon hardmask prior to annealing, as indicated at 1122. Alternatively or additionally, the annealed carbon hardmask can exhibit a change in sp³ carbon content less than or equal to 10% as measured by Raman spectroscopy compared to the unannealed carbon hardmask, as indicated at 1124.

Continuing, the method 1100 comprises, at step 1126, patterning the annealed carbon hardmask. The annealed carbon hardmask can be patterned using a suitable patterning process. The patterning process removes the hardmask from the region where directional etching of the underlying layers is to be performed to form a high aspect ratio feature.

The method 1100 further comprises, at step 1128, etching the substrate with the patterned hardmask. Etching proceeds in regions where the carbon hardmask was removed to expose the underlying layers. Any suitable method for directional etching can be used. Examples of directional etching include sputtering, ion milling and reactive ion etching (RIE). The etch selectivity of the annealed carbon hardmask can allow the etching of a higher aspect ratio feature than an unannealed carbon hardmask of a same thickness.

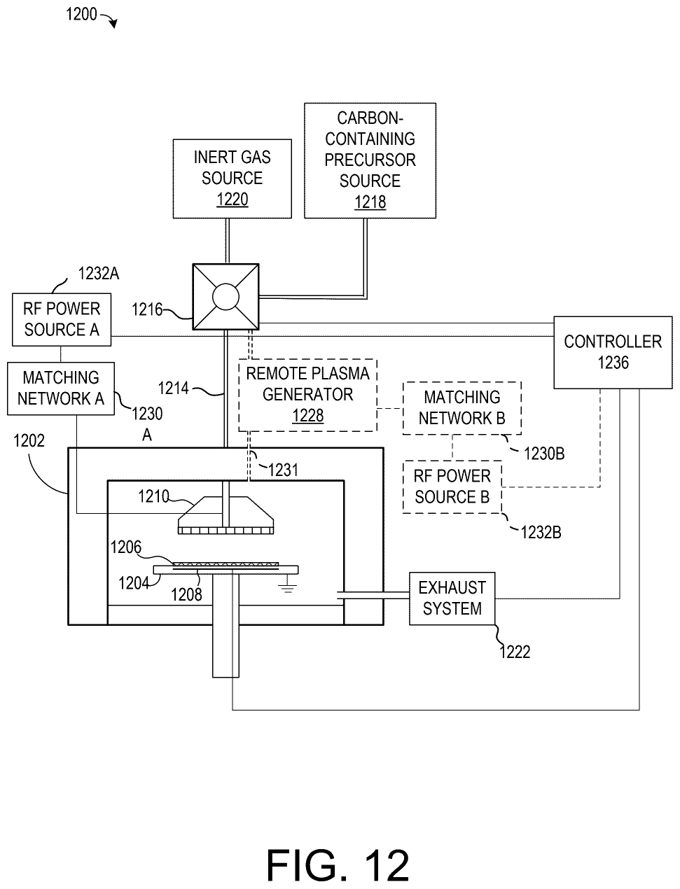

FIG. 12 shows a block diagram of an example processing tool 1200 for depositing a carbon hardmask. The processing tool 1200 can comprise an ALD tool or a CVD tool. The processing tool 1200 can be used to perform any of the carbon hardmask deposition processes described herein. The processing tool 1200 comprises a processing chamber 1202. The processing tool 1200 further comprises a substrate support 1204 within the processing chamber for supporting a substrate 1206. The substrate support 1204 can comprise a pedestal, a chuck, and/or any other suitable structure. The substrate support 1204 further can include a substrate heater 1208. The processing chamber 1202 further comprises a showerhead 1210. In other examples, a nozzle and/or other suitable inlet hardware can be used.

The processing tool 1200 further comprises one or more processing gas inlets for introducing processing gases into the processing chamber 1202. One example of a processing gas inlet 1214 is shown. In the depicted example, the processing gas inlet 1214 directs processes gases to the showerhead 1210. The processing tool 1200 further comprises flow control hardware 1216 for controlling the introduction of processing gases into the processing chamber 1202. The flow control hardware is connected to a carbon-containing precursor source 1218 and an inert gas source 1220.

The carbon-containing precursor source 1218 can contain any suitable carbon-containing precursor for depositing a carbon hardmask. Example carbon-containing precursors include can include alkanes having a general formula CₙH₂ₙ₊₂ where n is an integer in a range of 1 to 10 (such as methane, ethane, etc.), alkenes having a general formula CₙH₂ₙ where n=2 to 10 (such as ethylene, propylene, etc.), and alkynes having a general formula CₙH₂ₙ₋₂ where n=2 to 10 (such as acetylene, propyne, etc.), that are gas-phase under processing conditions. Other examples of carbon-containing precursors can comprise aliphatic and aromatic cyclic hydrocarbons, nitrogen-containing compounds including alkyl amines, and oxygen-containing compounds including alcohols, ketones, esters, aldehydes, and ethers, that are gas-phase under processing conditions.

The inert gas source 1220 can comprise any suitable inert gas. Examples include helium, neon, argon, krypton, xenon, and nitrogen.

The processing tool 1200 further comprises an exhaust system 1222. The exhaust system 1222 is configured to remove gases from the processing chamber 1202. The exhaust system 1222 can comprise any suitable hardware. Example hardware includes one or low vacuum pumps and one or more high vacuum pumps.

The substrate heater 1208 can be used to provide thermal energy to facilitate a deposition process. Further, in some examples, a plasma to facilitate the deposition process alternatively or additionally can be generated inside the processing chamber 1202 using a matching network A 1230A and a radiofrequency (RF) power source A 1232A. The plasma can be used to provide the energy to generate chemically active species in the gas phase. In the depicted example, the processing tool 1200 is configured to form a capacitively-coupled plasma. In other examples, an inductively coupled plasma, a microwave plasma, or other suitable plasma can be formed.

The matching network A 1230A and the RF power source A 1232A are configured to provide RF power to the showerhead 1210 as a powered electrode. The substrate support 1204 is configured as a grounded electrode. In other examples, power can be provided to the pedestal, and the showerhead can be grounded. The matching network A 1230A, the radiofrequency power source A 1232A, the substrate support 1204 and the showerhead 1210 can be referred to as an in-situ plasma generator. The term “in-situ plasma” generally represents a plasma to which the substrate 1206 is directly exposed during processing.

In some examples, a remote plasma generator 1228 can be used for a chamber cleaning process. The term “remote plasma” generally represents a plasma that is formed at a location remote from a substrate being processed or a chamber surface being cleaned. The reactive species can be delivered to the processing chamber 1202 via an inlet 1231. Where the optional remote plasma generator 1228 is used, the processing tool 1200 comprises an RF power source B 1232B electrically connected to the remote plasma generator 1228, and a matching network B 1230B for impedance matching of the RF power source 1232B. Further, in some examples, a remote plasma may be used in forming a carbon hardmask.

The RF power source A 1232A and the RF power source B 1232B can be configured for any suitable frequency and power. Examples of suitable frequencies include 400 kHz, 13.56 MHz, 27 MHz, 60 Mz, and 90 MHz. Examples of suitable powers include powers between 50 W (watts) and 50 kW. In some examples, the RF power sources 1232A and 1232B can be configured to operate at a plurality of different frequencies and/or powers. For example, either or both of the RF power sources can be configured as a dual frequency radiofrequency plasma source as disclosed herein.

The flow control hardware 1216 can be controlled to flow processing chemicals from the sources 1218 and 1220 into the processing chamber 1202 through the processing gas inlet 1214 to form a process gas. In some examples, the flow control hardware 1216 can also be configured to control the flow of one or more chemicals into the remote plasma generator 1228. The flow control hardware 1216 schematically represents any suitable components related to flowing gas into the processing chamber 1202 (and the remote plasma generator 1228 in some examples). For example, the flow control hardware 1216 can comprise one or more mass flow controllers and/or valves controllable to place a selected chemical source in fluid connection with the processing chamber 1202.

The controller 1236 is operatively coupled to substrate heater 1208, the flow control hardware 1216, the remote plasma generator 1228, the exhaust system 1222, the RF source A 1232A, and the RF power source B 1232B. The controller 1236 further can be operatively coupled to any other suitable component of the processing tool 1200. The controller 1236 is configured to control various functions of the processing tool 1200 to deposit a carbon hardmask.

For example, the controller 1236 is configured to operate the substrate heater 1208 to heat the substrate 1206. The controller 1236 is also configured to operate the flow control hardware 1216 to flow a selected chemical or mixture of chemicals at a selected rate into the processing chamber 1202. The controller 1236 is also configured to operate the exhaust system 1222 to remove gases from the processing chamber 1202. The controller 1236 is further configured to operate the flow control hardware 1216 and the exhaust system 1222 to maintain a selected pressure within the processing chamber 1202. The controller 1236 is further configured to control the plasma source 1232A to control the plasma generated in the processing chamber 1202. Furthermore, the controller 1236 is configured to operate the RF power source 1232B to form a remote plasma. In other examples, a processing tool can emit one or more of the remote plasma generator or the in-situ plasma generator.

In some examples, the controller 1236 can be configured to control the processing tool 1200 to anneal a substrate after deposition of a carbon hardmask. In such examples, the controller 1226 can be configured to heat the substrate 1206 to an annealing temperature and control a gaseous environment within the processing chamber 1202 for the annealing process.

However, performing deposition and annealing of a carbon hardmask in a same processing tool, such as processing tool 1200, can increase cycle time and decrease throughput. Additionally, the hardware components on the processing tool 1200 can degrade more rapidly with the longer processing times at elevated temperatures resulting from annealing. Also, in some examples, the substrate heater may not be capable of heating to a high enough temperature for the annealing process.

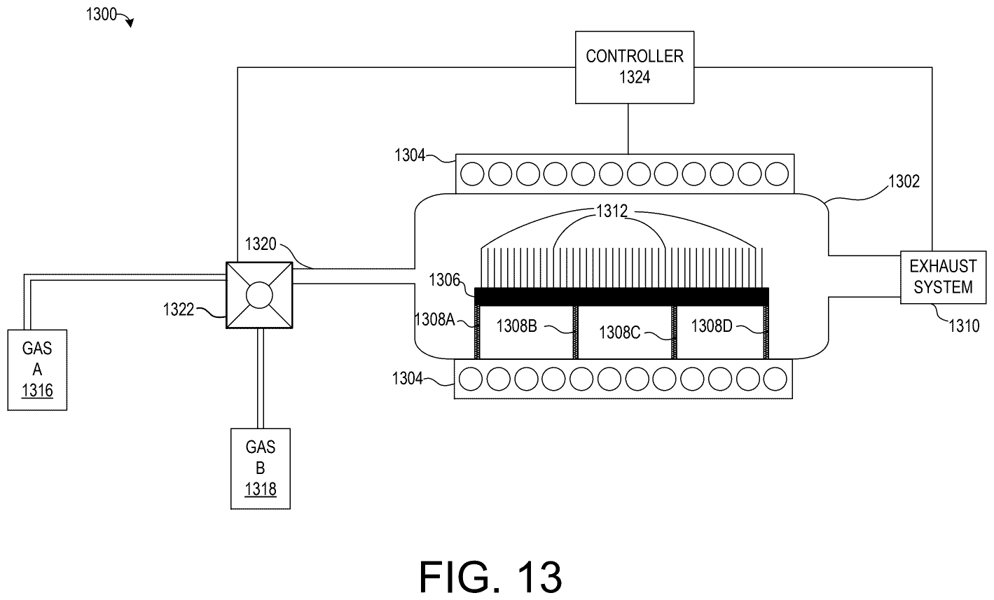

Thus, in other examples, annealing can be performed in an annealing tool. An annealing tool can be designed to withstand higher temperatures for longer periods and provide for higher throughput than can be achieved by annealing in a deposition tool. FIG. 13 shows a block diagram of an example annealing tool 1300. The annealing tool 1300 also can be referred to as a furnace. The annealing tool 1300 comprises an annealing chamber 1302, a heater 1304, and a substrate support 1306. The annealing tool 1300 further comprises supports 1308A, 1308B, 1308C and 1308D that support a substrate support 1306, and an exhaust system 1310. The substrate support 1306 can hold multiple substrates 1312 in some examples.

The annealing tool 1300 further comprises a gas source A 1316 and a gas source B 1318. In other examples, either more or fewer gas sources can be used. Gases are routed into the annealing chamber 1302 through a gas inlet 1320. The annealing tool 1300 further comprises flow control hardware 1322 for controlling the introduction of annealing gases into the annealing chamber 1302.

Gas source A 1316 can comprise an inert gas. Examples include helium, neon, argon, krypton, xenon and nitrogen. Inert gas can be provided to the annealing chamber 1302 during an annealing process. Inert gas also can be used a purge gas for the annealing chamber 1302. In some examples, two or more inert gas sources can be used to provide two or more different inert gases to the annealing chamber 1302. Examples include mixtures of argon and nitrogen. Gas source B 1318 optionally can comprise a reducing gas for annealing substrates 1312 in a reducing environment. An example of a reducing gas is H₂ or a mixture of H₂ and N₂.

The annealing chamber 1302 is heated by the heater 1304. In some examples, heat from the heater 1304 is transferred by convection to the annealing chamber 1302. In other examples, the heater 1304 can function as a radiant heater to heat the substrates 1312 by radiation. In some examples, the heater 1304 can be separated into zones along the length of the annealing chamber 1302, and each zone can be individually controlled independent of the other zones.

The exhaust system 1310 is configured to remove gases from the annealing chamber 1302. The exhaust system 1310 can comprise any suitable hardware. Example hardware comprises a vacuum pump.

The flow control hardware 1322 can be controlled to flow gases from the gas sources A and B 1316 and 1318 into the annealing chamber 1302 through the processing gas inlet 1320. The flow control hardware 1322 schematically represents any suitable components related to flowing gas into the annealing chamber 1302. For example, the flow control hardware 1322 can comprise one or more mass flow controllers and/or valves controllable to place a gas source in fluid connection with annealing chamber 1302.

The controller 1324 is operatively coupled to the heater 1304, the flow control hardware 1322, and the exhaust system 1310. The controller 1324 further can be operatively coupled to any other suitable component of annealing tool 1300 such as thermocouples. The controller 1324 is configured to control various functions of the annealing tool 1300 to perform an annealing process. The controller 1324 is also configured to control various functions of the annealing tool 1300 to perform an annealing chamber cleaning process.

In further examples, a carbon hardmask can be annealed using any other suitable tool than those shown in FIGS. 12 and 13. An annealed carbon hardmask according to the disclosed examples can demonstrate a lower hydrogen concentration, a higher modulus of elasticity, and a lower stress as compared to an unannealed carbon hardmask of a same thickness. This can provide the annealed carbon hardmask with a greater etch selectivity than the unannealed carbon hardmask. As such, the use of an annealed carbon hardmask can allow the etching of higher aspect ratio features than an unannealed carbon hardmask of a same thickness.

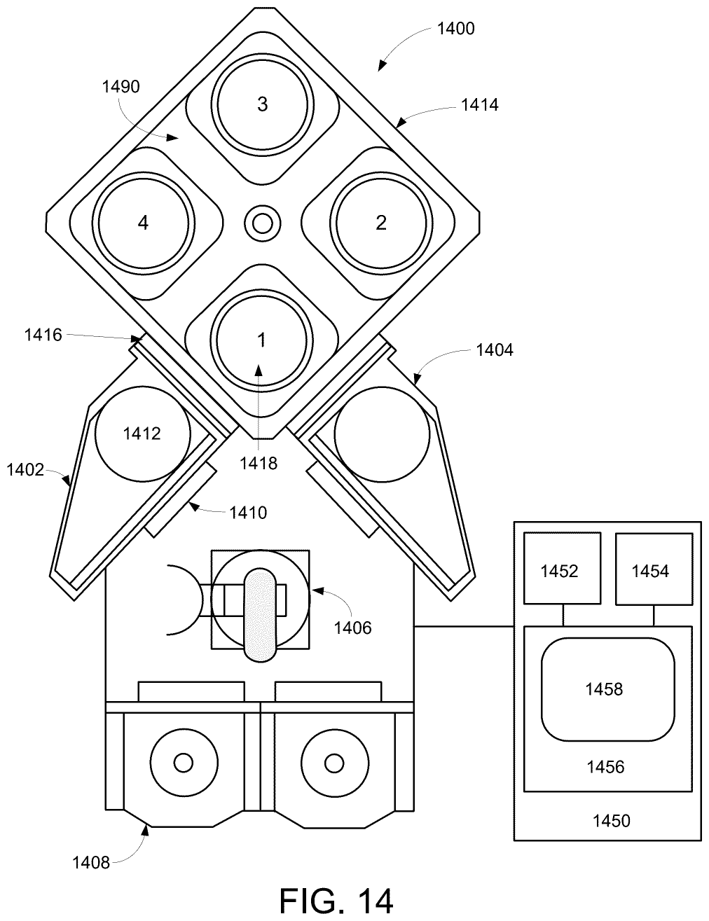

FIG. 14 shows a schematic view of an example of a multi-station processing tool 1400 with an inbound load lock 1402 and an outbound load lock 1404, either or both of which may comprise a remote plasma source. Multistation-processing tool can represent an implementation of processing tools 700 or 1200, as examples. A robot 1406, at atmospheric pressure, is configured to move wafers from a cassette loaded through a pod 1408 into inbound load lock 1402 via an atmospheric port 1410. A wafer is placed by the robot 1406 on a pedestal 1412 in the inbound load lock 1402, the atmospheric port 1410 is closed, and the load lock is pumped down. Where the inbound load lock 1402 comprises a remote plasma source, the wafer may be exposed to a remote plasma treatment in the load lock prior to being introduced into a processing chamber 1414. Further, the wafer also may be heated in the inbound load lock 1402 as well, for example, to remove moisture and adsorbed gases. Next, a chamber transport port 1416 to processing chamber 1414 is opened, and another robot (not shown) places the wafer into the reactor on a pedestal of a first station shown in the reactor for processing.

The depicted processing chamber 1414 comprises four process stations, numbered from 1 to 4 in the example shown in FIG. 14. Each station has a heated pedestal (shown at 1418 for station 1), and gas line inlets. It will be appreciated that in some examples, each process station may have different or multiple purposes. While the depicted processing chamber 1414 comprises four stations, it will be understood that a processing chamber according to the present disclosure may have any suitable number of stations. For example, in some examples, a processing chamber may have five or more stations, while in other examples a processing chamber may have three or fewer stations.

FIG. 14 also depicts an example of a wafer handling system 1490 for transferring wafers within processing chamber 1414. In some examples, wafer handling system 1490 may transfer wafers between various process stations and/or between a process station and a load lock. It will be appreciated that any suitable wafer handling system may be employed. Non-limiting examples include wafer carousels and wafer handling robots. FIG. 14 also depicts an example of a system controller 1450 employed to control process conditions and hardware states of processing tool 1400. System controller 1450 may include one or more memory devices 1456, one or more mass storage devices 1454, and one or more processors 1452. Processor 1452 may include a CPU or computer, analog and/or digital input/output connections, stepper motor controller boards, etc.

In some examples, system controller 1450 controls all of the activities of processing tool 1400. System controller 1450 executes system control software 1458 stored in mass storage device 1454, loaded into memory device 1456, and executed on processor 1452. System control software 1458 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by processing tool 1400. System control software 1458 may be configured in any suitable way. For example, various processing tool component subroutines or control objects may be written to control operation of the processing tool components necessary to carry out various processing tool processes in accordance with the disclosed methods. System control software 1458 may be coded in any suitable computer readable programming language.

In some examples, system control software 1458 may include input/output control (IOC) sequencing instructions for controlling the various parameters described above. Other computer software and/or programs stored on mass storage device 1454 and/or memory device 1456 associated with system controller 1450 may be employed in some examples. Examples of programs or sections of programs for this purpose include a substrate positioning program, a process gas control program, a pressure control program, a heater control program, and a plasma control program.

A substrate positioning program may include program code for processing tool components that are used to load the substrate onto pedestal 1418 and to control the spacing between the substrate and other parts of processing tool 1400.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some examples, there may be a user interface associated with system controller 1450. The user interface may include a display screen, graphical software displays of the apparatus and/or process conditions, and user input devices such as pointing devices, keyboards, touch screens, microphones, etc.

In some examples, parameters adjusted by system controller 1450 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 1450 from various processing tool sensors. The signals for controlling the process may be output on the analog and digital output connections of processing tool 1400. Non-limiting examples of processing tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed examples. In some examples, two or more of the stations may perform the same functions. Similarly, two or more stations may perform different functions. Each station can be designed/configured to perform a particular function/method as desired.

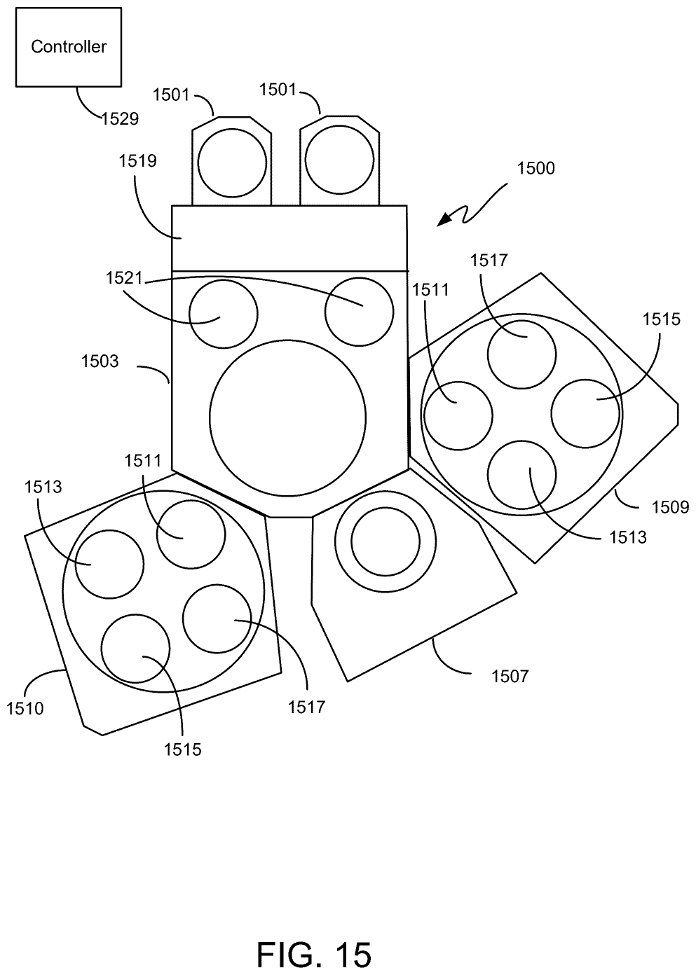

FIG. 15 is a block diagram of an example module cluster processing system suitable for conducting substrate processing in accordance with certain examples. The system 1500 includes a transfer module 1503. The transfer module 1503 provides a clean, pressurized environment to minimize risk of contamination of substrates being processed as they are moved between various reactor modules. Mounted on the transfer module 1503 are two multi-station reactors 1509 and 1510, each capable of performing atomic layer deposition (ALD) and/or chemical vapor deposition (CVD) according to certain examples. Reactors 1509 and 1510 may include multiple stations 1511, 1513, 1515, and 1517 that may sequentially or non-sequentially perform operations in accordance with disclosed examples. The stations may include a heated pedestal or substrate support, one or more gas inlets or showerhead or dispersion plate. Multi-station processing tool 1400 is an example of multi-station reactors 1509 and 1510.

Also mounted on the transfer module 1503 may be one or more single or multi-station modules 1507 capable of performing plasma or chemical (non-plasma) pre-cleans, or any other processes described in relation to the disclosed methods. The module 1507 may in some cases be used for various treatments to, for example, prepare a substrate for a deposition process. The module 1507 may also be designed/configured to perform various other processes such as etching, polishing or annealing. The system 1500 also includes one or more wafer source modules 1501, where wafers are stored before and after processing. An atmospheric robot (not shown) in the atmospheric transfer chamber 1519 may first remove wafers from the source modules 1501 to loadlocks 1521. A wafer transfer device (generally a robot arm unit) in the transfer module 1503 moves the wafers from loadlocks 1521 to and among the modules mounted on the transfer module 1503.

In various examples, a system controller 1529 is employed to control process conditions during deposition. The controller 1529 will typically include one or more memory devices and one or more processors. A processor may include a CPU or computer, analog and/or digital input/output connections, stepper motor controller boards, etc.

The controller 1529 may control all of the activities of the deposition apparatus. The system controller 1529 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 1529 may be employed in some examples.

Typically there will be a user interface associated with the controller 1529. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 1529. The signals for controlling the process are output on the analog and digital output connections of the deposition apparatus 1500.

The system software may be designed or configured in many different ways. For example, various chamber component subroutines or control objects may be written to control operation of the chamber components necessary to carry out the deposition processes (and other processes, in some cases) in accordance with the disclosed examples. Examples of programs or sections of programs for this purpose include substrate positioning code, process gas control code, pressure control code, and heater control code.

In some implementations, the system controller 1529 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 1529, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, an annealing chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Although the foregoing examples have been described in some detail for purposes of clarity of understanding, it will be apparent that certain changes and modifications may be practiced within the scope of the appended claims. Examples disclosed herein may be practiced without some or all of these specific details. In other instances, well-known process operations have not been described in detail to not unnecessarily obscure the disclosed examples. Further, while the disclosed examples will be described in conjunction with specific examples, it will be understood that the specific examples are not intended to limit the disclosed examples. It should be noted that there are many alternative ways of implementing the processes, systems, and apparatus of the present examples. Accordingly, the present examples are to be considered as illustrative and not restrictive, and the examples are not to be limited to the details given herein.

1. A method of forming an ashable hardmask (AHM) film, comprising:
receiving a substrate in a processing chamber;
exposing the substrate in the processing chamber to a process gas comprising one or more hydrocarbon precursors and one or more halide-containing species; and
depositing on the substrate the AHM film by a plasma enhanced chemical vapor deposition (PECVD) process using the process gas, wherein the PECVD process comprises:
igniting a plasma generated by a dual radio frequency (RF) plasma source including a high frequency (HF) component and a low frequency (LF) component;
wherein the HF component power is maintained as unpulsed during deposition, and
wherein the LF component power is pulsed during deposition with a duty cycle of between 10% and 75%.

2. The method of claim 1, wherein the one or more halide-containing species comprise a fluorine-containing species.

3. The method of claim 1, wherein a flow rate of the one or more halide-containing species is between 1% and 20% of a flow rate of the one or more hydrocarbon precursors.

4. The method of claim 1, wherein the HF component power is at least 350 W per 300 mm wafer and wherein the LF component power is at least 1250 W per 300 mm wafer.

5. The method of claim 1, wherein the processing chamber is at a temperature between 150° C. and 550° C. during the PECVD process.

6. The method of claim 1, wherein the processing chamber is at a pressure between 0.5 torr and 5 torr during the PECVD process.

7. The method of claim 1, wherein the AHM film has a modulus of at least 120 GPa.

8. The method of claim 1, wherein the AHM film has a hardness of at least 14 GPa.

9. The method of claim 1, wherein the AHM film has a hydrogen content less than 20 atomic percent.

10. A processing tool, comprising:
a processing chamber;
flow control hardware configured to control a flow of processing chemicals into the processing chamber;
a dual radiofrequency plasma source; and
a controller configured to control the processing tool to
control the flow control hardware to expose a substrate in the processing chamber to a process gas comprising one or more hydrocarbon precursors and one or more halide-containing species; and
control the dual radiofrequency plasma source to
ignite a plasma comprising a high frequency (HF) component and a low frequency (LF) component;
maintain the HF component power as unpulsed during deposition, and
pulse the LF component power during deposition with a duty cycle of between 10% and 75%.

11. The processing tool of claim 10, wherein the one or more halide-containing species comprise a fluorine-containing species.

12. A method of processing a substrate, the substrate comprising a carbon hardmask, the method comprising:
placing the substrate in an annealing tool, the carbon hardmask having a first stress and a first hydrogen content; and
annealing the substrate to form an annealed carbon hardmask that has a second stress and a second hydrogen content, wherein the second stress is lower than the first stress, and the second hydrogen content is lower than the first hydrogen content.

13. The method of claim 12, wherein the second, lower hydrogen content of the annealed carbon hardmask is equal to or less than 10 atomic percent.

14. The method of claim 12, wherein the second, lower stress of the annealed carbon hardmask is greater than or equal to 1 MPa and less than or equal to 100 MPa.

15. The method of claim 12, wherein annealing the substrate such that the annealed carbon hardmask comprises the second, lower stress comprises annealing the substrate such that the annealed carbon hardmask exhibits a modulus of elasticity greater than or equal to 60 GPa and less than or equal to 250 GPa.
